(19) United States
(12) Patent Application Publication
(10) Pub. No.: US 2001/0036676 A1
(43) Pub. Date: Nov. 1, 2001

(54) Semiconductor wafer polishing endpoint detecting system and method therefor

(75) Inventors: Hideo Mitsuhashi, Tokyo (JP); Shinji Yamagata, Tokyo (JP); Hiroshi Naka, Tokyo (JP); Katsuhisa Ookawa, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/839,131

(22) Filed: Apr. 23, 2001

(30) Foreign Application Priority Data
Apr. 26, 2000 (JP) 125057/2000
Sep. 28, 2000 (JP) 295475

(51) Int. Cl. H01L 21/00; G01R 31/26; C23F 1/02; H01L 21/66

(52) U.S. Cl. 438/8; 438/16; 156/345

(57) ABSTRACT

A semiconductor wafer polishing endpoint detection system and a method therefor can detect a polishing endpoint accurately. A first polishing endpoint detecting means compares the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after the absolute value of the first averaged gradient data becomes greater than or equal to a given value, or when a ratio that the value of the first averaged gradient data becomes greater than or equal to the first endpoint judgment threshold value is greater than or equal to a predetermined ratio.

### BACKGROUND OF THE INVENTION

1. Field of the Invention

The present invention relates to a semiconductor wafer polishing end point detecting system and a method therefor. More particularly, the invention relates to a detecting system for detecting a polishing endpoint in a polishing device of a semiconductor wafer.

2. Description of the Related Art

When wirings or vias of various devices are to be formed on a semiconductor wafer, it has been taken a method in which, after depositing a metal layer over the entire surface of the wafer covering an insulation layer, unnecessary portion is removed by chemical and mechanical polishing. In the polishing process, polish finishing point has to be detected with high precision. If polishing is not performed sufficiently, the metal layer should be left on the surface of the semiconductor wafer to cause shorting between the wiring. On the other hand, if polishing is excessive, the wiring layer may cause lacking of the cross-sectional area. One of prior arts for detecting the polishing endpoint has been proposed in Japanese Patent No. 2561812 (U.S. Pat. No. 5,433,651).

FIG. 10 is an illustration showing a construction of one example of the prior art. A semiconductor wafer polishing endpoint detecting system shown in FIG. 10 is constructed with a polishing bed 2 provided with a predetermined dimension of detection hole 43, an abrasive cloth 3 on the polishing bed 2 and provided with a detection hole 43 at the same position as the polishing bed 2, a view window 44 sealing the detection hole 43 as polishing fluid in-flow preventing means for preventing in-flow of a polishing fluid into a detection optical system from the detection hole 43, a laser light source 46 for irradiating an inspection light 45 of a predetermined diameter onto a polishing surface of the wafer as a polishing object through the detection hole 43 and the view window 44, a photodetector 48 receiving a regular reflection light 47 reflected on the wafer for measuring a light amount to output as a light amount signal o, averaging means 49 for averaging the light amount signal o per one turn of the wafer 1 and outputting a third averaged data pin discrete manner, and polishing end point detection means 50 comparing the averaged data p output from the averaging means 40 with a predetermined threshold value detected by a reflection index of a material formed on the wafer 1, pattern density and a structure of the wafer 1, such as pattern density or the like and detecting a timing when the averaged data p is decreased below the threshold value as the polishing endpoint.

At first, the inspection light 45 irradiated from the third laser light source 46 is irradiated on the polishing surface of the wafer 1 through the detection hole 43 and the view window 44 and reflected on the wafer 1. The third regular reflection light 47 reflected on the wafer 1 is received by the photodetector 48 and the light amount is measured to be output as the light amount signal o. Next, the averaging means 49 receives the light amount signal o to calculate an average per one turn of the wafer to output one turn averaged data p in discrete manner.

A time varying averaged data p derived by the averaging means 49 is large value at initial stage of polishing since the metal layer 30 having high reflection index (see FIG. 2) is deposited over the entire surface of the uppermost layer of the wafer 1. Next, according to progress of polishing, the metal layer 30 is removed to expose the insulation layer 28 having low reflection index, or in the alternative, when the insulation layer 29 is light transmitting, to expose the insulation layer 29 to pass the inspection light therethrough to reflect the same on the substrate having low reflection index. Therefore, the reflection light amount is decreased according to progress of polishing.

A value of the averaged data p at the polishing endpoint should be substantially the same when a structure of wafer 1, such as a reflection index of the material of the layer formed on the wafer 1 and a pattern density or the like are the same. Therefore, in the polishing endpoint detecting means 50, the averaged data p output from the averaging means 49 with the predetermined threshold value determined by the structure of the wafer 1, such as the reflection index of the material of the layer formed on the wafer 1, the pattern density or the like, for detecting endpoint of polishing at a timing where the averaged data p is decreased to be smaller than the threshold value.

However, the method for detecting the polishing endpoint by comparing the reflection light amount of the single waveform, encounters a problem which is not applicable for certain material of the semiconductor, certain layer thickness, certain structure of the wafer 1, such as shape, density of the wiring pattern and so forth. Particularly, in case of the wafer having barrier layer 31, the averaged data p of the reflected light may be increased after once decreased significantly and then reach the polishing endpoint. In such case, in comparison with the threshold value, a value the same as that at the polishing endpoint is present at a timing before increasing to hinder accurate detection of the polishing endpoint.

### SUMMARY OF THE INVENTION

An object of the present invention is to provide a semiconductor wafer polishing endpoint detection system and a method therefor, which can detect a polishing endpoint accurately.

According to the first aspect of the present invention, a semiconductor wafer polishing endpoint detecting system comprises:

a first laser light source as a light source for a first inspection light of a predetermined wavelength;

a first irradiation means for irradiating the first inspection light on the wafer with a predetermined diameter and a predetermined angle;

a second laser light source as a light source for a second inspection light of a wavelength different from that of the first inspection light;

a second irradiation means for irradiating the second inspection light to the same irradiating position and the same diameter as the first inspection light at a predetermined angle;

a first photodetector located on a regular reflection light axis of the first inspection light reflected on the wafer, receiving the regular reflection light for outputting a first light amount signal;

a second photodetector located on a regular reflection light axis of the second inspection light reflected on the wafer, receiving the regular reflection light for outputting a second light amount signal;

first averaging means and second averaging means for receiving the first light amount signal and the second light amount signal and averaging the first light amount signal and the second light amount signal per a period synchronous with an integer multiple of rotation period of the wafer in discrete manner for outputting a first averaged data and a second averaged data;

initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

detecting start judgment means for disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

first reference light amount detecting means and second reference light amount detecting means for detecting one of maximum values and averaged values of the first averaged data and the second averaged data during a period from polishing endpoint detection disabled condition by the initial variation canceling means to enabling of polishing endpoint detecting operation by the detection start judgment means to output as first reference light amount value and second reference light amount value;

light amount correcting means for calculating a ratio of the first reference light amount value and the second reference light amount value and multiplying the second averaged data by the ratio of the first reference light amount value and the second reference light amount value for outputting a corrected light amount data;

light amount difference calculating means for calculating a difference between the first averaged data and the corrected light amount data for outputting as a light amount difference data;

first threshold value calculating means for outputting a value derived by multiplying the first reference light amount value by a predetermined value as a first endpoint judgment threshold value for detecting polishing endpoint;

first averaged gradient calculating means for calculating an averaged gradient between an averaged value of a plurality of retraced past data and a data at current measuring timing of the light amount difference data and an averaged value of a plurality of past data of the light amount difference data; and

first polishing endpoint detecting means for comparing the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after the absolute value of the first averaged gradient data becomes greater than or equal to a given value, or when a ratio that the value of the first averaged gradient data becomes greater than or equal to the first endpoint judgment threshold value is greater than or equal to a predetermined ratio.

In the preferred construction, the semiconductor wafer polishing endpoint detecting system further comprises time axis correction means located between the light amount correcting means and the light amount difference calculating means for receiving the corrected light amount data output from the light amount correction means, detecting a timing where a difference between a value of the first averaged data at a timing where the first averaged data is decreased from a maximum value in a predetermined amount and a value of the corrected light amount signal before and after the timing where the first averaged data is decreased from a maximum value in a predetermined amount, becomes minimum, for deriving a time difference between two timings as offset period, and shifting a time axis of the corrected light amount for the derived offset period for outputting a second corrected light amount data to the light amount difference calculating means.

According to the second aspect of the present invention, a semiconductor wafer polishing endpoint detecting system comprises:

a first laser light source as a light source for a first inspection light of a predetermined wavelength;

a first irradiation means for irradiating the first inspection light on the wafer with a predetermined diameter and a predetermined angle;

a second laser light source as a light source for a second inspection light of a wavelength different from that of the first inspection light;

a second irradiation means for irradiating the second inspection light to the same irradiating position and the same diameter as the first inspection light at a predetermined angle;

a first photodetector located on a regular reflection light axis of the first inspection light reflected on the wafer, receiving the regular reflection light for outputting a first light amount signal;

a second photodetector located on a regular reflection light axis of the second inspection light reflected on the wafer, receiving the regular reflection light for outputting a second light amount signal;

first averaging means and second averaging means for receiving the first light amount signal and the second light amount signal and averaging the first light amount signal and the second light amount signal per a period synchronous with an integer multiple of rotation period of the wafer in discrete manner for outputting a first averaged data and a second averaged data;

initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

detecting start judgment means for disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

first reference light amount detecting means and second reference light amount detecting means for detecting one of maximum values and averaged values of the first averaged data and the second averaged data during a period from polishing endpoint detection disabled condition by the initial variation canceling means to enabling of polishing endpoint detecting operation by the detection start judgment means to output as first reference light amount value and second reference light amount value;

light amount ratio calculating means for calculating a ratio of the first averaged data and the second averaged data for outputting a light amount ratio data;

first averaged gradient calculating means for calculating an averaged gradient between an averaged value of a plurality of retraced past data and a data at current measuring timing of the light amount ratio data and an averaged value of a plurality of past data of the light amount difference data;

first threshold value calculating means for outputting a value derived by multiplying the first reference light amount value by a predetermined value as a first endpoint judgment threshold value for detecting polishing endpoint and

first polishing endpoint detecting means for comparing the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after the absolute value of the first averaged gradient data becomes greater than or equal to a given value, or when a ratio that the value of the first averaged gradient data becomes greater than or equal to the first endpoint judgment threshold value is greater than or equal to a predetermined ratio.

The semiconductor wafer polishing endpoint detection system may use at least three inspection lights as the inspection lights, mutually different combinations each consisted of two inspection lights are used in parallel for detecting the polishing endpoint.

The first polishing endpoint detecting means may compare the value of the first averaged gradient data and a value of the first endpoint judgment threshold value for making judgment of end of polishing when the value of the first averaged gradient data is smaller than or equal to the first endpoint judgment threshold value continuously for a predetermined number of times, when the value of the first averaged gradient data is smaller than or equal to the first endpoint judgment threshold value for a number of times greater than or equal to a given number of times in total after the absolute value of the first averaged gradient data becomes greater than or equal to a given value, or when a ratio that the value of the first averaged gradient data becomes smaller than or equal to the first endpoint judgment threshold value is greater than or equal to a predetermined ratio.

According to the third aspect of the present invention, a semiconductor wafer polishing endpoint detecting system comprises:

a first laser light source as a light source for a first inspection light of a predetermined wavelength;

a first irradiation means for irradiating the first inspection light on the wafer with a predetermined diameter and a predetermined angle;

a second laser light source as a light source for a second inspection light of a wavelength different from that of the first inspection light;

a second irradiation means for irradiating the second inspection light to the same irradiating position and the same diameter as the first inspection light at a predetermined angle;

a first photodetector located on a regular reflection light axis of the first inspection light reflected on the wafer, receiving the regular reflection light for outputting a first light amount signal;

a second photodetector located on a regular reflection light axis of the second inspection light reflected on the wafer, receiving the regular reflection light for outputting a second light amount signal;

first averaging means and second averaging means for receiving the first light amount signal and the second light amount signal and averaging the first light amount signal and the second light amount signal per a period synchronous with an integer multiple of rotation period of the wafer in discrete manner for outputting a first averaged data and a second averaged data;

initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

detecting start judgment means for disabling polishing endpoint detecting operation until one of the first averaged data or the second averaged data is varied to a predetermined value or a predetermined multiple for adapting to fluctuation in signal fluctuation period in the initial stage of polishing due to fluctuation of polishing speed;

first reference light amount detecting means and second reference light amount detecting means for detecting one of maximum values and averaged values of the first averaged data and the second averaged data during a period from polishing endpoint detection disabled condition by the initial variation canceling means to enabling of polishing endpoint detecting operation by the detection start judgment means to output as first reference light amount value and second reference light amount value;

first threshold value calculating means for outputting a value derived by multiplying the first reference light amount value by a predetermined value as a first endpoint judgment threshold value for detecting polishing endpoint;

second averaged gradient calculating means and third averaged gradient calculating means for calculating averaged gradients by connecting an averaged value of a plurality of retraced past data and the value at the current timing among the first averaged data and the second averaged data and an averaged data of a plurality of retraced past light amount difference data for outputting as a second averaged gradient data and a third averaged gradient data,

first light amount increase detecting means and second light amount increase detecting means detecting the second averaged gradient data and the third averaged gradient data in positive value,

second threshold value calculating means for outputting a value derived by multiplying the second reference light amount data output from the second reference light amount detecting means by a predetermined value as a second endpoint judgment threshold value for detecting the polishing endpoint on the side of the second inspection light, and

second polishing endpoint detecting means and the third polishing endpoint detecting means for comparing the values of the second and third averaged gradient data and the endpoint judgment threshold value after the first light amount increase detecting means and the second light amount increase detection means detect the second averaged gradient data and the third averaged gradient data in positive for making judgment of end of polishing when the values of the second averaged gradient data and the third averaged gradient data become values greater than or equal to the endpoint judgment threshold values continuously for a predetermined number of times or more, when the second averaged gradient data and the third averaged gradient data become the value greater than or equal to the endpoint judgment threshold values for a number of times greater than or equal to the predetermined times in total after the absolute value of said averaged gradient data becomes greater than or equal to a given value, or when a ratio that the second averaged gradient data and the third averaged gradient data become greater than or equal to the endpoint judgment threshold value becomes greater than or equal to a predetermined ratio.

The second polishing endpoint detecting means and the third polishing endpoint detecting means may compare the values of the second averaged gradient data and the third averaged gradient data and the endpoint judgment threshold value after detection of the second averaged gradient data and the third averaged gradient data become positive values, for making judgement of end of plishing when the values of the second averaged gradient data and the third averaged gradient data become values smaller than or equal to the endpoint judgment threshold values continuously for a predetermined number of times or more, when the second averaged gradient data and the third averaged gradient data become the values smaller than or equal to the endpoint judgment threshold values for a number of times greater than or equal to the predetermined times in total after the absolute value of the averaged gradient becomes greater than or equal to the predetermined value, or when a ratio that the second averaged gradient data and the third averaged gradient data become smaller than or equal to the endpoint judgment threshold value bacomes greater than or equal to a predetermined ratio.

At least three inspection lights having mutually different wavelength may be used for detecting polishing endpoint in parallel. The inspection light may be single to perform polishing end point alone.

According to the fourth aspect of the present invention, a semiconductor wafer polishing endpoint detecting system comprises:

multi-wavelength measurement means having a plurality of light sources respectively having different wavelength and one or more light receiving portion, irradiating a plurality of lights having different wavelengths on the same light axis as a sixth inspection light, receives a sixth regular reflection light as reflection light from the wafer to measure light receiving amount per wavelengths for outputting a plurality of received light amount signals;

sixth irradiating means for guiding the sixth inspection light including a plurality of wavelengths emitted from the multi-wavelength measuring means for irradiating to the wafer at a predetermined diameter and a predetermined angle;

sixth light receiving means for guiding the sixth regular reflection light reflected from the wafer to the multi-wavelength measuring means;

first averaging means and second averaging means for receiving the first light amount signal and the second light amount signal and averaging the first light amount, signal and the second light amount signal per a period synchronous with an integer multiple of rotation period of the wafer in discrete manner for outputting a first averaged data and a second averaged data;

initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

detecting start judgment means for disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

first reference light amount detecting means and second reference light amount detecting means for detecting one of maximum values and averaged values of the first averaged data and the second averaged data during a period from polishing endpoint detection disabled condition by the initial variation canceling means to enabling of polishing endpoint detecting operation by the detection start judgment means to output as first reference light amount value and second reference light amount value;

light amount correcting means for calculating a ratio of the first reference light amount value and the second reference light amount value and multiplying the second averaged data by the ratio of the first reference light amount value and the second reference light amount value for outputting a corrected light amount data;

light amount difference calculating means for calculating a difference between the first averaged data and the corrected light amount data for outputting as a light amount difference data;

first threshold value calculating means for outputting a value derived by multiplying the first reference light amount value by a predetermined value as a first endpoint judgment threshold value for detecting polishing endpoint;

first averaged gradient calculating means for calculating an averaged gradient between an averaged value of a plurality of retraced past data and a data at current measuring timing of the light amount difference data and an averaged value of a plurality of past data of the light amount difference data; and

first polishing endpoint detecting means for comparing the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after the absolute value of the first averaged gradient data becomes greater than or equal to a given value, or when a ratio that the value of the first averaged gradient data becomes greater than or equal to the first endpoint judgment threshold value is greater than or equal to a predetermined ratio.

The sixth irradiating means, the sixth light receiving means and the multi-wavelength measuring means may be integrated in a single unit. The sixth irradiating means and the sixth light receiving means are integrated in a single unit.

According to the fifth aspect of the invention, a semiconductor wafer polishing endpoint detecting method comprises the steps of:

emitting a first inspection light of a predetermined wavelength;

irradiating the first inspection light on the wafer with a predetermined diameter and a predetermined angle;

emitting a second inspection light of a wavelength different from that of the first inspection light;

irradiating the second inspection light to the same irradiating position and the same diameter as the first inspection light at a predetermined angle;

receiving the regular reflection light of the first inspection light for outputting a first light amount signal;

receiving the regular reflection light of the second inspection light for outputting a second light amount signal;

receiving the first light amount signal and the second light amount signal and averaging the first light amount signal and the second light amount signal per a period synchronous with an integer multiple of rotation period of the wafer in discrete manner for outputting a first averaged data and a second averaged data;

disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

detecting one of maximum values and averaged values of the first averaged data and the second averaged data during a period from polishing endpoint detection disabled condition by the initial variation canceling step to enabling of polishing endpoint detecting operation by the detection start judgment step to output as first reference light amount value and second reference light amount value;

calculating a ratio of the first reference light amount value and the second reference light amount value and multiplying the second averaged data by the ratio of the first reference light amount value and the second reference light amount value for outputting a corrected light amount data;

calculating a difference between the first averaged data and the corrected light amount data for outputting as a light amount difference data;

outputting a value derived by multiplying the first reference light amount value by a predetermined value as a first endpoint judgment threshold value for detecting polishing endpoint;

calculating an averaged gradient between an averaged value of a plurality of retraced past data and a data at current measuring timing of the light amount difference data and an averaged value of a plurality of past data of the light amount difference data; and

comparing the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after absolute value of the first averaged gradient data becomes greater than or equal to a given value, or when a ratio that the value of the first averaged gradient data becomes greater than or equal to the first endpoint judgment threshold value is greater than or equal to a predetermined ratio.

The semiconductor wafer polishing endpoint detecting method may further comprise the step of receiving the corrected light amount data output from the light amount correction means, detecting a timing where a difference between a value of the first averaged data at a timing where the first averaged data is decreased from a maximum value in a predetermined amount and a value of the corrected light amount signal before and after the timing where the first averaged data is decreased from a maximum value in a predetermined amount, becomes minimum, for deriving a time difference between two timings as offset period, and shifting a time axis of the corrected light amount for the derived offset period for outputting a second corrected light amount data to the step of calculating the light amount difference data.

According to the sixth aspect of the invention, a semiconductor wafer polishing endpoint detecting method comprises:

emitting a first inspection light of a predetermined wavelength;

irradiating the first inspection light on the wafer with a predetermined diameter and a predetermined angle;

emitting a second inspection light of a wavelength different from that of the first inspection light;

irradiating the second inspection light to the same irradiating position and the same diameter as the first inspection light at a predetermined angle;

receiving the regular reflection light of the first inspection light for outputting a first light amount signal;

receiving the regular reflection light of the second inspection light for outputting a second light amount signal;

receiving the first light amount signal and the second light amount signal and averaging the first light amount signal and the second light amount signal per a period synchronous with an integer multiple of rotation period of the wafer in discrete manner for outputting a first averaged data and a second averaged data;

disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

detecting one of maximum values and averaged values of the first averaged data and the second averaged data during a period from polishing endpoint detection disabled condition by the initial variation canceling means to enabling of polishing endpoint detecting operation by the detection start judgment means to output as first reference light amount value and second reference light amount value;

calculating a ratio of the first averaged data and the second averaged data for outputting a light amount ratio data;

calculating an averaged gradient between an averaged value of a plurality of retraced past data and a data at current measuring timing of the light amount ratio data and an averaged value of a plurality of past data of the light amount difference data;

calculating a ratio of the first reference light amount value and the second reference light amount value and multiplying the second averaged data by the ratio of the first reference light amount value and the second reference light amount value for outputting a corrected light amount data;

outputting a value derived by multiplying the first reference light amount value by a predetermined value as a first endpoint judgment threshold value for detecting polishing endpoint; and

comparing the value of the first averaged gradient data and the first endpoint judgment threshold value for making judgment of end of polishing of wafer when the value of the first averaged gradient data is greater than or equal to the first endpoint judgment threshold value continuously for a predetermined number of times, when the value of the first averaged gradient data is greater than or equal to the first endpoint judgment threshold value for a number of times greater than or equal to a given number of times in total after the absolute value of the first averaged gradient data becomes greater than or equal to a given value, or when a ratio that the value of the first averaged gradient data becomes greater than or equal to the first endpoint judgment threshold value is greater than or equal to a predetermined ratio.

The semiconductor wafer polishing endpoint detection method may uses at least three inspection lights as the inspection lights, mutually different combinations each consisted of two inspection lights are used in parallel for detecting the polishing endpoint.

In the step of detecting polishing endpoint, the value of the first averaged gradient data is compared with a value of the first endpoint judgment threshold value for making judgment of end of polishing when the value of the first averaged gradient data is smaller than or equal to the first endpoint judgment threshold value continuously for a predetermined number of times, when the value of the first averaged gradient data is smaller than or equal to the first endpoint judgment threshold value for a number of times greater than or equal to a given number of times in total after the absolute value of the first averaged gradient data becomes greater than or equal to a given value, or when a ratio that the value of the first averaged gradient data becomes smaller than or equal to the first endpoint judgment threshold value is greater than or equal to a predetermined ratio.

According to the seventh aspect of the invention, a semiconductor wafer polishing endpoint detecting method comprises the steps of:

emitting a first inspection light of a predetermined wavelength;

irradiating the first inspection light on the wafer with a predetermined diameter and a predetermined angle;

emitting a second inspection light of a wavelength different from that of the first inspection light;

irradiating the second inspection light to the same irradiating position and the same diameter as the first inspection light at a predetermined angle;

receiving the regular reflection light of the first inspection light for outputting a first light amount signal;

receiving the regular reflection light of the second inspection light for outputting a second light amount signal;

receiving the first light amount signal and the second light amount signal and averaging the first light amount signal and the second light amount signal per a period synchronous with an integer multiple of rotation period of the wafer in discrete manner for outputting a first averaged data and a second averaged data;

disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;

disabling polishing endpoint detecting operation until the first averaged data or the second averaged data is varied to a predetermined value or a predetermined multiple for adapting to fluctuation in signal fluctuation period in the initial stage of polishing due to fluctuation of polishing speed;

detecting one of maximum values and averaged values of the first averaged data and the second averaged data during a period from polishing endpoint detection disabled condition by the initial variation canceling step to enabling of polishing endpoint detecting operation by the detection start judgment step to output as first reference light amount value and second reference light amount value;

outputting a value derived by multiplying the first reference light amount value by a predetermined value as a first endpoint judgment threshold value for detecting polishing endpoint;

calculating averaged gradients by connecting an averaged value of a plurality of retraced past data and the value at the current timing among the first averaged data and the second averaged data and an averaged data of a plurality of retraced past light amount difference data for outputting as a second averaged gradient data and a third averaged gradient data,

detecting the second averaged gradient data and the third averaged gradient data in positive value,

outputting a value derived by multiplying the first reference light amount by a predetermined value as a first endpoint judgment threshold value for detecting the polishing endpoint, and

comparing the values of the second averaged gradient data and the third averaged gradient data and the endpoint judgment threshold value after the second averaged gradient data and the third averaged gradient data become positive value, for making judgment of end of polishing when the values of the second averaged gradient data and the third averaged gradient data become values greater than or equal to the endpoint judgment threshold value continuously for a predetermined number of times or more, when the second averaged gradient data and the third averaged gradient data become the value greater than or equal to the endpoint judgment threshold values for a number of times greater than or equal to the predetermined times in total the absolute value of the averaged gradiant becomes greater than or equal to the given value, or when a ratio that the second averaged gradient data and the third averaged gradient data become greater than or equal to the endpoint judgment threshold value is greater than or equal to a predetermined ratio, are provided in place of the light amount correcting step, the light amount difference calculating step, the first gradient calculating step and the first polishing endpoint detecting step.

In the step of detecting polishing endpoint, the values of the second averaged gradient data and the third averaged gradient data are compared with the endpoint judgment threshold value after the second averaged gradient data and the third averaged gradient data become positive values, for making judgement of and of polishing when the values of the second averaged gradient data and the third averaged gradient data become values smaller than or equal to the endpoint judgment threshold values continuously for a predetermined number of times or more, when the second averaged gradient data and the third averaged gradient data become the value smaller than or equal to the endpoint judgment threshold value for a number of times greater than or equal to the predetermined times in total after the absolute value of the averaged gradient becomes greater than or equal to the predetermined value, or when a ratio that the second averaged gradient data and the third averaged gradient data become smaller than or equal to the endpoint judgment threshold value is greater than or equal to a predetermined ratio.

At least three inspection lights having mutually different wavelength may be used for detecting polishing endpoint in parallel. The inspection light may be single to perform polishing end point alone.

### BRIEF DESCRIPTION OF THE DRAWINGS

The present invention will be understood more fully from the detailed description given hereinafter and from the accompanying drawings of the preferred embodiment of the present invention, which, however, should not be taken to be limitative to the invention, but are for explanation and understanding only.

In the drawings:

FIG. 1 is a block diagram showing the first embodiment of a semiconductor wafer polishing endpoint detecting system according to the present invention;

FIG. 2 is an illustration showing a semiconductor wafer structure for which the present invention is applied;

FIG. 3 is an illustration showing a polishing period and variation of first and second averaged data;

FIG. 4 is an illustration showing variation of the first and second data after correction of the averaged data of FIG. 3;

FIG. 5 is a block diagram showing the second embodiment of a semiconductor wafer polishing endpoint detecting system according to the present invention;

FIG. 6 is a block diagram showing the third embodiment of a semiconductor wafer polishing endpoint detecting system according to the present invention;

FIG. 7 is a block diagram showing the fourth embodiment of a semiconductor wafer polishing endpoint detecting system according to the present invention;

FIG. 8 is an illustration showing one example of variation of the first averaged data, the second averaged data, a light amount ratio data according to progress of polishing in the embodiment of FIG. 7;

FIG. 9 is a block diagram showing the fifth embodiment of a semiconductor wafer polishing endpoint detecting system according to the present invention; and

FIG. 10 is an illustration for explaining the prior art.

### DESCRIPTION OF THE PREFERRED EMBODIMENT

The present invention will be discussed hereinafter in detail in terms of the preferred embodiment of the present invention with reference to the accompanying drawings. In the following description, numerous specific details are set forth in order to provide a thorough understanding of the present invention.

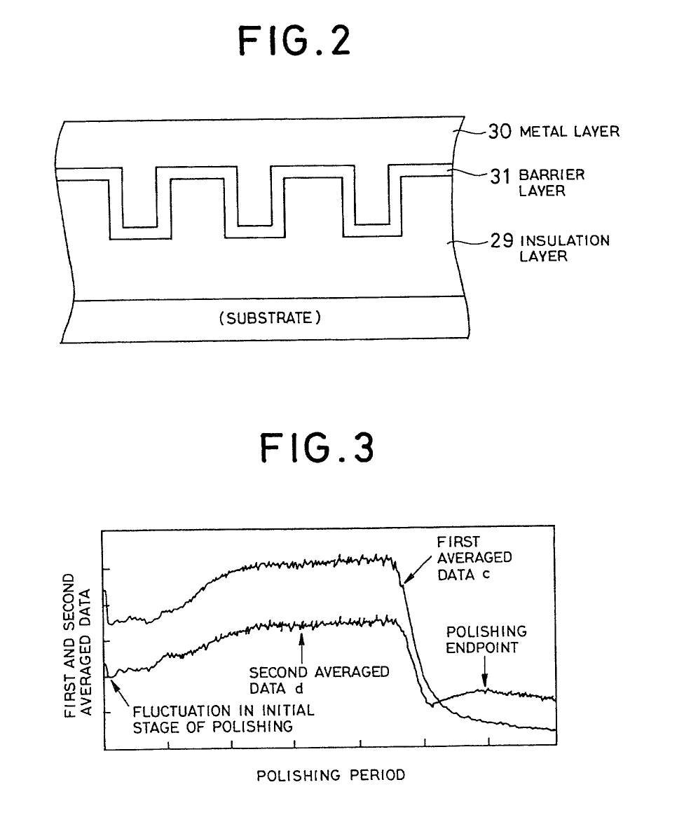

The first embodiment of a semiconductor wafer polishing endpoint detecting system is applicable for polishing a semiconductor wafer having a film called as a barrier film 31 for preventing diffusion of metal of a metal layer, disposed between a metal layer 30 as an uppermost layer and a lower insulation layer 29, as shown in FIG. 2, and adapted for accurately detecting polishing endpoint.

FIG. 2 is a section showing one example of a semiconductor wafer having the barrier film, as an object of polishing, to which the present invention is applied. On the uppermost layer of the wafer 1, the metal layer 30 is deposited over the entire surface covering the insulation layer 29. Between the metal layer 30 and the insulation layer 29, a barrier film 31 is formed for preventing metal of the metal layer 30 from diffusion.

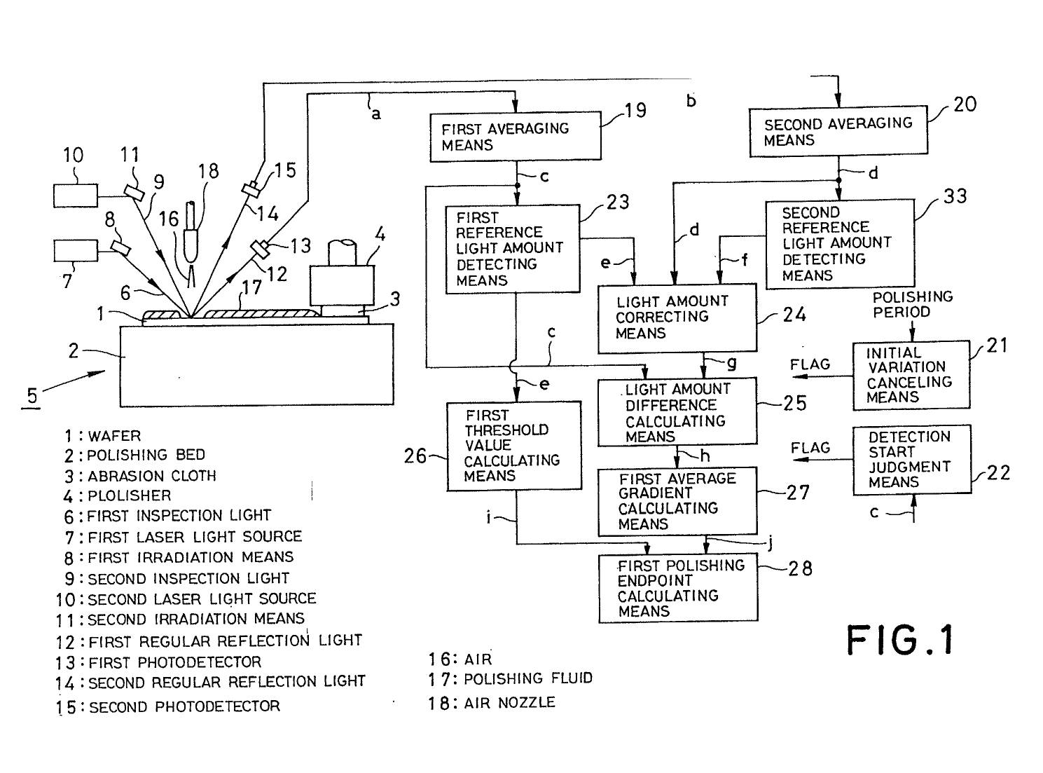

FIG. 1 is an illustration showing a construction of the first embodiment of the semiconductor wafer polishing endpoint detecting system according to the present invention. Referring to FIG. 1, the semiconductor wafer polishing endpoint detecting system, to which the present invention is applied, is designed for detecting a polishing endpoint in a polishing device which drives the semiconductor wafer 1 to rotate on a polishing bed 2 within a horizontal plane, contacts an abrasion cloth 3 onto a surface of the wafer 1 to be polished (which surface will be hereinafter referred to as “polishing surface”) with a predetermined pressure by a polisher 4 with supplying a polishing fluid 17, drives the polisher for rotation about an axis perpendicular to the polishing surface of the wafer 1 and for swing motion in parallel to the polishing surface of the wafer 1 for performing polishing. It should be noted that the object of polishing is to remove the metal layer 30 and the barrier film 31 until the insulation layer 29 is exposed for forming a metal wiring.

A first inspection light 6 of a predetermined wavelength emitted from a first laser light source 7 is irradiated in a predetermined diameter toward a predetermined position on the wafer 1, at which the insulation layer 29 is to be exposed during polishing, at a predetermined angle sufficiently smaller than a total reflection angle by a first irradiation means 8 constructed with a reflection mirror or the like. A second inspection light 9 emitted from a second laser light source 10 and having a wavelength different from that of the first inspection light 6 is irradiated in the same diameter as the first inspection light 6 toward the same position as that irradiated by the first inspection light 6, at a predetermined angle sufficiently smaller than a total reflection angle, by a second irradiation means 11 constructed with a reflection mirror or the like. The first inspection light 6 and the second inspection light 9 are reflected on the polishing surface of the wafer 1.

A first regular reflection light 12 and a second regular reflection light 14 reflected on the wafer 1 are received by a first photodetector 13 and a second photodetector 15 arranged on respective regular reflection light axes to be measured received light amounts to be output as a first light amount signal “a” and a second light amount signal “b”.

At this time, patterns of different densities are arranged on the wafer 1. Since the wafer 1 is rotated during polishing operation, the reflected light amount is varied depending upon densities of the patterns, the first light amount signal “a” and the second light amount signal “b” become periodically varying signals. Progress of polishing appears in variation of the signal removed the periodic variation. By a first averaging means 19 and a second averaging means 20 respectively corresponding to the first light amount signal “a” and the second light amount signal “b”, at every timing with an interval synchronous with an integer multiple of a rotational period of the polishing bed 2 carrying the wafer 1, for example, at every one turn of the polishing bed 2, the first light amount signal “a” and the second light amount signal “b” are averaged to be output as a first averaged data “c” and a second averaged data “d” per one turn in discrete manner.

Upon polishing the wafer 1 having the barrier film, the first averaged data “c” and the second averaged data “d” are varied as follow according to progress of polishing.

\mathring{1} initial stage of polishing, relatively large variation is caused.

\mathring{2} After elapse of a predetermined period from initiation of polishing, the light amount starts to be decreased significantly.

\mathring{3} After starting decreasing of the light amount, the light amount is decreased. During a certain period from starting decreasing of the light amount, the first averaged data “c” and the second averaged data “d” have substantially the same light amount decreasing ratio (decreasing of the light amount per a unit period) according to decreasing of the light amount.

\mathring{4} After the foregoing certain period from starting of decreasing of the light amount, the first averaged data “c” and the second averaged data “b” start to be differentiated with each other.

\mathring{5} After polishing endpoint, the light amount variation ratios of the first averaged data “c” and the second averaged data “b” become substantially the same.

Relatively large variation in the initial stage of polishing is caused due to unstability of polishing immediately after initiation of polishing or non-uniformity of initial condition before polishing. Therefore, even when the periodic variations are removed by the first averaging means 19 and the second averaging means 20, variations irrespective of progress of polishing appear to be a cause of erroneous judgment. Therefore, by employing initial variation canceling means 21 and detection start judgment means 22, erroneous judgment of the polishing endpoint due to variation irrespective of progress of polishing in the initial stage of polishing, is prevented.

The initial variation canceling means 21 compares a preliminarily set given period and a polishing period from initiation timing to a current timing. If the polishing period up to the current timing is less than or equal to the preliminarily set given period, the initial variation canceling means 21 sets a first operation enabling and disabling flag to “disable” for disabling polishing endpoint detecting operation. At a timing where the polishing period up to the current timing exceeds the preliminarily set given period, the initial variation canceling means 21 sets the first operation enabling and disabling flag to “enable”.

In the detection start judgment means 22 detects a maximum value among the first averaged data “c” or the second averaged data d and derives a difference or ratio of the detected maximum value and the first averaged data “c” or the second averaged data “d”. If the difference or ratio is less than or equal to a preliminarily set given value or a given multiple, the detection start judgment means 22 sets a second operation enabling and disabling flag toll disable to disable the polishing endpoint detecting operation. When the difference or ratio this derives exceeds the preliminarily set given value or a given multiple, the detection start judgment means 22 sets a second operation enabling and disabling flag to “enable”.

By using both of the initial variation canceling means 21 and the detection start judgment means 22, the polishing endpoint detecting operation is held disabled as long as one of the first operation disabling and enabling flag and the second operation disabling and enabling flag is held “disable”, and only when both flags are set to “enable”, the polishing endpoint detecting operation is enabled.

The timing where the light amount starts to decrease significantly, is the timing where the metal layer 30 of the portion other than those to be wiring becomes thin enough to pass through the light or a part of the metal layer 30 is removed to expose the barrier film 31, and thus a reflection index of the barrier film starts to influence for the light amount. Decreasing of the light amount is caused due to difference of the reflection indexes between the metal layer 30 and the barrier film 31. Namely, decreasing of the light amount is caused for the fact that, at wavelengths of the first inspection light 6 and the second inspection light 9, the reflection index of the metal layer 30 is greater than the reflection index of the barrier film 31.

After starting of decreasing of the light amount, the light amount is decreased so that the first averaged data licit and the second averaged data “d” have substantially the same light amount decreasing ratio up to a certain timing. From the certain timing, either the first averaged data “c” or the second averaged data “d”, for example, the first averaged data “c”, may have greater light amount decreasing than that in the second averaged data “d”. The reason why difference in decreasing of the light amount is caused is that after removal of the barrier layer 31, the reflection indexes of the lower layer structure are different between the first inspection light 6 and the second inspection light 9. For example, in the following disclosure, the reflection index of the first inspection light 6 is greater than the reflection index of the second inspection light 9.

According to progress of polishing, the barrier film 31 becomes thinner to start to pass through the light. Then, the reflection index of the lower layer starts to influence for the light amount. Due to difference of reflection indexes at difference wavelength in the lower layer, the first averaged data “c” and the second averaged data “d” become different to crease a difference therebetween. On the other hand, after the polishing end point, the difference between the first averaged data “c” and the second averaged data “d” becomes substantially constant. The reason is that according to progress of polishing, the surface exposed is varied from the metal layer 30 to the barrier film 31, and then from the barrier film 31 to the lower structure, i.e. the insulation layer 29. Once the lower structure, i.e. the insulation layer 29, is exposed, the surface is not varied any further. Strictly, due to variation of layer thickness in the lower structure, interference condition of the light may be varied to slightly vary the first averaged data “c” and the second averaged data “d”. However, in comparison with variation set forth above, the variation speed is significantly low. Therefore, with the length of period to make judgment whether the difference becomes constant, it can be discriminated from the variation of the light amount before the polishing endpoint.

Accordingly, the polishing endpoint can be detected by monitoring variation of difference of the decreasing ratio of the first averaged data “c” and the second averaged data “d” and detecting a timing where the difference between the first averaged data “c” and the second averaged data “d” becomes constant. Therefore, by deriving the difference between the first averaged data “c” and the second averaged data “d”, the polishing endpoint is detected by detecting a timing where the difference between the first averaged data and the second averaged data becomes substantially constant.

At first, in deriving the difference between the first averaged data “c” and the second averaged data “d”, by correcting difference of measuring condition of the first averaged data “c” and the second averaged data “d”, references of the variation amounts are made coincident with each other. As the reference, measured values when the entire surface of the wafer is covered with the metal layer 30 is used. For this purpose, first reference light amount detecting means 23 and second reference light amount detecting means 33 are provided. The first reference light amount detecting means 23 and second reference light amount detecting means 33 detect maximum values or averaged values of the first averaged data “c” and the second averaged data “d” during a period from the end of the disabled condition of the polishing endpoint detection at the initial stage of polishing by the initial variation canceling means 21 to judgment of starting of detection of the polishing endpoint by the detection start judgment means 22, for outputting as a first reference light amount value “e” and “a” second reference light amount value “f”. Light amount correcting means 24 derives a ratio of the first reference light amount value “e” and the second reference light amount value “f” output from the first reference light amount detecting means 23 and the second reference light amount detecting means 33 and multiplies the second averaged data “d” by the derived ratio of the first reference light amount value “e” and the second reference light amount value “f” to output as a corrected light amount data “g”.

Next, light amount difference calculating means 25 calculates a difference between the first averaged data “c” and the corrected light amount data “g” to output a light amount difference data “h”. Using this light amount difference data “h”, the polishing endpoint is detected. As set forth above, at the polishing endpoint, the light amount difference data “h” becomes substantially constant. Therefore, in order to detect the polishing endpoint, the timing where the light amount difference data “h” becomes constant. For this purpose, a differentiated value of the light amount difference data “h” for detecting the timing where the differentiated value becomes close to zero.

It should be noted that since the light amount difference data “h” has fine error component, the difference values may be derived at a plurality of measuring point to use the averaged value thereof for judgment of the polishing endpoint. Namely, by first averaged gradient deriving means 27, among the light amount difference data “h” output from the light amount difference calculating means 25, a value derived by averaging a plurality of retraced data and the currently measured data the value derived by averaging a plurality of retraced data of the light amount difference data at a past timing are connected to derives an averaged gradient for outputting as a first gradient data “j”. A first polishing endpoint detecting means 28 compares the first averaged gradient data with a first endpoint judgment threshold value “i”. If the first averaged gradient data “j” becomes greater than or equal to the first endpoint judgment threshold value “i” continuously for a number of times greater than or equal to a given times, if the value of the first averaged gradient data becomes greater than or equal to the first endpoint judgment threshold value “i” for a times greater than or equal to the predetermined times in total from a timing where the absolute value of the averaged gradient becomes greater than or equal to the predetermined value, or if a ratio of the first averaged gradient data “j” greater than or equal to the first endpoint judgment threshold value becomes greater than or equal a predetermined ratio, judgment is made that polishing of wafer 1 is finished.

It should be noted that the reflection index after removal of the barrier film 31, is determined by interference in the insulation layer 29 as undercoat layer after removal of the barrier film 31. Therefore, in certain kind of the wafer 1, it is possible that polishing endpoint cannot be detected when the reflection index resulting from interference in the insulation layer 29 accidentally matches with the reflection index in the barrier film 31 if only two inspection lights are used. In this case, three or more inspection lights having respectively different wavelength are used. Among those three or more inspection lights, with different combinations respectively consisted of two inspection lights, polishing endpoint detecting operations are performed in parallel to accurately detect the polishing endpoint of the wafer 1. By providing three or more inspection lights with different wavelengths, a plurality of kinds of wafers 1 with different film thickness are polished, any one of different combination of two inspection lights out of three or more inspection lights may cause difference of the decreasing ratio of the averaged data, and any of the combination, the polishing endpoint is detected.

On the other hand, when irradiating positions and irradiation diameters of the first inspection light 6 and the second inspection light 9 are different, and fluctuation is caused in the polishing speed in the radial direction of the wafer, error in time should be caused between variation of the first averaged data “c” and variation of the second averaged data “d”. This is because when differences of the irradiating position and the irradiation diameter of the first inspection light 6 and the second inspection light 9 and fluctuation in polishing in the radial direction of the wafer, reflection indexes of the portions where the irradiating positions of the first inspection light 6 and the second inspection light 9 do not overlap influences with each other.

In such case, if a difference between the first averaged data “c” and the corrected light amount data “g” is calculated by the light amount difference calculating means 25 as is, correct light amount difference data depending upon variation of the surface of wafer 1 cannot be obtained. Therefore, error in time direction of variation of the first averaged data “c” and variation of the second averaged data “d” is corrected.

Particularly, a value of the first averaged data “c” at a timing where the first averaged data “c” is decreased from the maximum value in the predetermined ratio or the predetermined amount and a value of the corrected light amount data “g” before and after the timing where the first averaged data “c” is decreased from the maximum value in the predetermined ratio or the predetermined amount are compared to detect a timing where the difference becomes minimum to calculate a time difference between two timings as an offset period to calculate a second corrected light amount data “k” shifted the time axis of the corrected light amount data “g” for the offset period. Subsequently, in place of the corrected light amount data “g”, the second corrected light amount data “k” to perform polishing endpoint detection in the similar matter to the above.

On the other hand, in the wavelength of the first inspection light 6 or the second inspection light 9, it is possible in certain kind of the barrier film 31 and the certain lower layer structure to be exposed at the polishing endpoint that the reflection index of the barrier film 31 is smaller than the reflection index of the lower layer structure exposed at the polishing endpoint. In this case, the first averaged data “c” or the second averaged data “d” is once risen at a timing where the barrier film 31 is exposed and the reflection index of the lower layer structure influences after significantly lowering the signal, and after polishing endpoint, is maintained substantially constant or again lowered.

In such case, a differential value of the first averaged data “c” or the second averaged data “d” is calculated, to take a timing where the sign of the differential value once becomes “positive” and then the value becomes close to zero, as polishing endpoint. At this time, number of the inspection light is not specifically limited to two. The reflection index of the lower layer structure is varied by interference in the insulation layer 29. According to the thickness of the insulation layer 29, it is therefore possible that signal variation incapable of detecting either inspection light, if the wavelengths of the inspection lights are only two.

In such case, respectively different three or more inspection lights are used to detect the polishing endpoint in parallel with each other so that any one of the inspection lights the polishing endpoint may be detected. On the other hand, if the layer thickness of the insulation layer 29 of the wafer 1 as object is limited, and the reflection index of the barrier film 31 at the polishing endpoint is smaller than the reflection index in the case where the lower layer structure is exposed, the inspection light may be one.

The first embodiment of the semiconductor wafer polishing endpoint detection system according to the present invention will be discussed in greater detail. The semiconductor wafer polishing endpoint detecting system shown in FIG. 1 is premised for application to the semiconductor wafer polishing device 5 which includes the polishing bed 2 located in opposition to the lower surface of the wafer I as polishing object, holds the wafer and drives the wafer 1 in the horizontal plane, the abrasion cloth 3 located at supper surface side as the polishing surface of the wafer 1 and contacting with the wafer 1, and the polisher 4 rotating the abrasion cloth 3 about the shaft perpendicular to the polishing surface of the wafer 1 and performing swing motion in parallel to the wafer 1 with urging the abrasion cloth 3 onto the wafer 1 at a predetermined pressure.

In this device 5, a first laser light source 7 as a light source for the first inspection light 6 of a predetermined wavelength, the first irradiation means 8 for irradiating the first inspection light 6 emitted from the first laser light source 7 on the wafer 1 at a predetermined diameter and angle, a second laser light source 10 as a light source of the second inspection light 9 having a wavelength different from that of the first inspection light 6, the second irradiating means 11 for irradiating the second inspection light 9 emitted from the second laser light source 10 to the same position as the irradiating position of the first inspection light 6 at the same diameter in the predetermined angle, the first photodetector 13 located on a regular reflection light axis of the first inspection light 6 reflected on the polishing surface of the wafer 1, receiving the first regular reflection light 12 for measuring the light amount thereof for outputting as the first light amount signal “a”, the second photodetector 15 located on a regular reflection light axis of the second inspection light 9 reflected on the polishing surface of the wafer 1, receiving the second regular reflection light 14 for measuring the light amount thereof for outputting as the second light amount signal “b”.

The semiconductor wafer polishing endpoint detecting system further includes an air nozzle 18 blowing an air toward the position irradiating the first inspection light 6 and the second inspection light 9 on the wafer 1 at a predetermined pressure and a flow rate for removing the polishing fluid 17 from irradiating region of the first inspection light 6 and the second inspection light 9 in an extent not causing a problem in detection of variation of the reflected light amount, and the first averaging means 19 and the second averaging means 20 receiving the first light amount signal “a” and the second light amount signal “b”, averaging the first light amount signal “a” and the second light amount signal “b” per a period synchronous with integer multiple of rotational period of the polishing bed 2 carrying the wafer 1, and outputting the first averaged data “c” and the second averaged data “d” in discrete manner.

Furthermore, in order to prevent detection of signal variation due to unstability of polishing immediately after initiating polishing and signal variation before stabilizing polishing of the initial stage of initiation of polishing due to difference at initial condition before polishing, the initial canceling means 21 for disabling polishing endpoint detecting operation from initiation of polishing to elapse of a predetermined period, and detection start judgment means 22 for disabling the polishing endpoint detecting operation during significant variation of the first averaged data or the second averaged data associating with progress of polishing, for example until the first averaged data c or the second averaged data “d” is varied in a predetermined magnitude or predetermined multiples for adapting to fluctuation of signal fluctuation period at the initial stage of polishing due to fluctuation of polishing speed, are provided.

Furthermore, the first reference light amount detecting means 23 and second reference light amount detecting means 33 detect maximum values or averaged values of the first averaged data “c” and the second averaged data “d” during a period from the end of the disabled condition of the polishing endpoint detection at the initial stage of polishing by the initial variation canceling means 21 to judgment of starting of detection of the polishing endpoint by the detection start judgment means 22, for outputting as a first reference light amount value “e” and a second reference light amount value “f”. The light amount correcting means 24 deriving a ratio of the first reference light amount value “e” and the second reference light amount value “f” output from the first reference light amount detecting means 23 and the second reference light amount detecting means 33 after disabling of the polishing endpoint at the initial stage of polishing by the initial canceling means 21 and until judgment of initiation of detecting operation of the polishing endpoint by the detection start judgment means 22 and multiplying the second averaged data d by the derived ratio of the first reference light amount value e and the second reference light amount value “f” to output as a corrected light amount data “g”, and the light amount difference calculating means 25 calculating the difference between the first averaged data “c” and the corrected light amount data “g” for outputting as the light amount difference data “h” are provided.

On the other hand, first threshold value calculating means 26 for outputting a value derived by multiplying the first reference light amount value “e” by the predetermined value as a first endpoint judgment threshold value “i” for detecting the polishing endpoint, first averaged gradient deriving means 27 for deriving a first averaged gradient by connecting, among the light amount difference data “h” output from the light amount difference calculating means 25, a value derived by averaging a plurality of retraced data and the currently measured data, the value derived by averaging a plurality of retraced data of the light amount difference data at a past timing outputting as a first gradient data “j”, first polishing endpoint detecting means 28 compares the first averaged gradient data “j” with a first endpoint judgment threshold value “i” for making judgment of end of polishing of the wafer when the first averaged gradient data “j” becomes greater than or equal to the first endpoint judgment threshold value “i” continuously for a number of times greater than or equal to a given times, when the value of the first averaged gradient data becomes greater than or equal to the first endpoint judgment threshold value “i” for a times greater than or equal to the predetermined times in total from a timing where the absolute value of the averaged gradient becomes greater than or equal to the predetermined value, or when a ratio of the first averaged gradient data “j” greater than or equal to the first endpoint judgment threshold value becomes greater than or equal a predetermined ratio, are provided.

FIG. 2 is a section showing one example of the wafer having the barrier layer as object for polishing of the present invention. On the uppermost layer of the wafer 1, the metal layer 30 is deposited over the entire surface for covering the insulation layer 29. In order to prevent metal of the metal layer from diffusing, the barrier layer 31 is formed between the metal layer 30 as the uppermost layer and the lower insulation layer 29.

The polishing device 5 forms the metal wiring by polishing the metal layer 30 until the insulation layer 29 is exposed. Polishing of the wafer 1 is performed by driving the semiconductor wafer 1 to rotate on a polishing bed 2 within a horizontal plane, contacts an abrasion cloth 3 onto a surface of the wafer 1 to be polished with a predetermined pressure by a polisher 4 with supplying a polishing fluid 17, and driving the polisher for rotation about an axis perpendicular to the polishing surface of the wafer 1 and for swing motion in parallel to the polishing surface of the wafer 1 for performing polishing. It is required to comprehend progress of polishing to terminate polishing at an appropriate polishing condition. If polishing is not performed sufficiently, the metal layer should be left on the surface of the semiconductor wafer to cause shorting between the wiring. On the other hand, if polishing is excessive, the wiring layer may cause lacking of the cross-sectional area or formation of step on the polishing surface due to difference of polishing speed between the insulation layer 29 and the metal layer 30.

Operation of the first embodiment of the semiconductor wafer polishing endpoint detecting system will be discussed.

The first inspection light 6 of a predetermined wavelength emitted from the first laser light source 7 is irradiated in a predetermined diameter toward a predetermined position on the wafer 1, at which the insulation layer 29 is to be exposed during polishing, at a predetermined angle sufficiently smaller than a total reflection angle by a first irradiation means 8 constructed with a reflection mirror or the like. A second inspection light 9 emitted from a second laser light source 10 and having a wavelength different from that of the first inspection light 6 is irradiated in the same diameter as the first inspection light 6 toward the same position as that irradiated by the first inspection light 6, at a predetermined angle sufficiently smaller than a total reflection angle, by a second irradiation means 11 constructed with a reflection mirror or the like. At this time, the wavelength of the first inspection light 6 and the wavelength of the second inspection light 9 are selected so that the reflection index at the metal layer 30 is higher than the reflection index at the barrier film 31.

Next, the first inspection light 6 and the second inspection light 9 are reflected on the wafer 1. The first regular reflection light 12 and the second regular reflection light 14 reflected on the wafer 1 are received by the first photodetector 13 and the second photodetector 15 arranged on respective regular reflection light axes to be measured received light amounts to be output as the first light amount signal “a” and the second light amount signal “b”.

It should be noted that the polishing fluid 17 is removed by blowing an air by the air nozzle 18 so that shape of the beam the first and second regular reflection lights 12 and 14 may not influence for affecting measurement by fluctuation of the surface of meniscus of the polishing fluid 17 on the wafer 1, so that the polishing fluid 17 will never interfere irradiation of the first inspection light 6 and the second inspection light 9. Also, the first photodetector 13 and the second photodetector 15 are those converting light into an electric signal, such as a photodiode, multiplier photo tube or the like.

At this time, patterns of different densities are arranged on the wafer 1. Since the wafer 1 is rotated during polishing operation, the reflected light amount is varied depending upon densities of the patterns, the first light amount signal “a” and the second light amount signal “b” become periodically varying signals. Progress of polishing appears in variation of the signal removed the periodic variation. By a first averaging means 19 and a second averaging means 20 respectively corresponding to the first light amount signal “a” and the second light amount signal “b”, at every timing with an interval synchronous with an integer multiple of a rotational period of the polishing bed 2 carrying the wafer 1, for example, at every one turn of the polishing bed 2, the first light amount signal “a” and the second light amount signal “b” are averaged to be output as the first averaged data “c” and the second averaged data “d” per one turn in discrete manner.

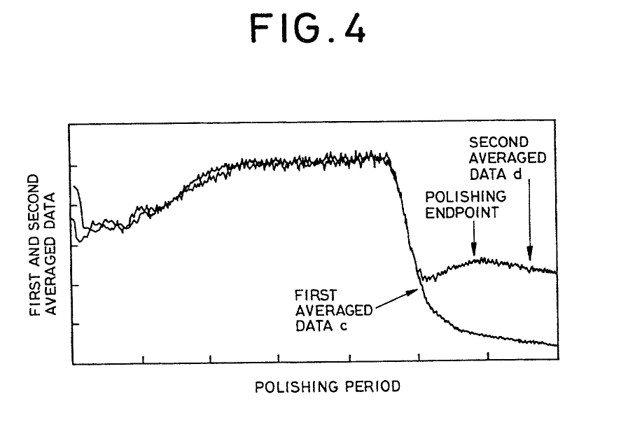

FIG. 3 is a graph showing one example of variation of the first averaged data “c” and the second averaged data “d” associating with progress of polishing when the wafer 1 with the barrier film shown in FIG. 2 is polished. On the other hand, FIG. 4 is a graph showing result of correction performed for the first averaged data “c” and the second averaged data “d” so that two data are consistent with each other before significantly decreasing the light amount so as to facilitate understanding of difference of the light amount decreasing radio of the first averaged data “c” and the second averaged data

Upon polishing the wafer 1 having the barrier film, the first averaged data “c” and the second averaged data “d” are varied as follow according to progress of polishing.

\mathring{1} At initial stage of polishing, relatively large variation is caused.

\mathring{2} After elapse of a predetermined period from initiation of polishing, the light amount starts be decreased significantly.

\mathring{3} After starting decreasing of the light amount, the light amount is decreased. During a certain period from starting decreasing of the light amount, the first averaged data “c” and the second averaged data “d” have substantially the same light amount decreasing ratio (decreasing of the light amount per a unit period) according to decreasing of the light amount.

\mathring{4} After the foregoing certain period from starting of decreasing of the light amount, the first averaged data “c” and the second averaged data “d” start to be differentiated with each other.

\mathring{5} After polishing endpoint, the light amount variation ratios of the first averaged data “c” and the second averaged data “d” become substantially the same.

Relatively large variation in the initial stage of polishing is caused due to unstability of polishing immediately after initiation of polishing or non-uniformity of initial condition before polishing. Therefore, even when the periodic variation is removed by the first averaging means 19 and the second averaging means 20, variation irrespective of progress of polishing appears to be a cause of erroneous judgment. Therefore, by employing initial variation canceling means 21 and detection start judgment means 22, erroneous judgment of the polishing endpoint due to variation irrespective of progress of polishing in the initial stage of polishing, is prevented.

The initial variation canceling means 21 compares a preliminarily set given period and a polishing period from initiation timing to a current timing. If the polishing period up to the current timing is less than or equal to the preliminarily set given period, the initial variation canceling means 21 sets a first operation enabling and disabling flag to “disable” for disabling polishing endpoint detecting operation. At a timing where the polishing period up to the current timing exceeds the preliminarily set given period, the initial variation canceling means 21 sets the first operation enabling and disabling flag to “enable”.

The detection start judgment means 22 detects a maximum value among the first averaged data “c” or the second averaged data “d” and derives a difference or ratio of the detected maximum value and the first averaged data “c” or the second averaged data “d”. If the difference or ratio this derives is less than or equal to a preliminarily set given value or a given multiple, the detection start judgment means 22 sets a second operation enabling and disabling flag to “disable” to disable the polishing endpoint detecting operation. When the difference or ratio this derives exceeds the preliminarily set given value or a given multiple, the detection start judgment means 22 sets a second operation enabling and disabling flag to “enable”.

By using both of the initial variation canceling means 21 and the detection start judgment means 22, the polishing endpoint detecting operation is held disabled as long as one of the first operation disabling and enabling flag and the second operation disabling and enabling flag is held “disable”, and only when both flags are set to “enable”, the polishing endpoint detecting operation is enabled.

Signal variation in the initial stage of polishing is large in at starting of polishing and is gradually decreased subsequently. On the other hand, the polishing speed should be fluctuated per the wafer 1. At this time, when erroneous detection is to be prevented only by the initial variation canceling means 21, since the initial variation canceling means 21 prevents the judgement operation during the predetermined period, the polishing endpoint may be erroneously detected by fluctuation of time up to the end of polishing, in case where the speed of polishing varies. For example, when the period to the end of polishing is short, polishing should be finished before initiation of the polishing endpoint detecting operation. Conversely, when the period to finish polishing is too long, the polishing endpoint detecting operation is initiated despite of the fact that signal is still varying. On the other hand, when erroneous detection is to be prevented only by the detection start judgment means 22, since the detection start judgment means 22 is means for starting polishing endpoint detecting operation by detecting significant variation of the signal, significant variation of polishing may be erroneously detected as the polishing end point.

Accordingly, by employing both of the initial variation canceling means 21 and the detection start judgment means 22, to prevent erroneous judgment for a period exceeding the significant signal variation at the initial stage of polishing by the initial variation canceling means 21 and erroneous judgment due to subsequent small signal variation by the detection start judgment means 22.

The timing where the light amount starts to decrease significantly, is the timing where the metal layer 30 of the portion other than those to be wiring becomes thin enough to pass through the light or a part of the metal layer 30 is removed to expose the barrier film 31, and thus a reflection index of the barrier film starts to influence for the light amount. Decreasing of the light amount is caused due to difference of the reflection indexes between the metal layer 30 and the barrier film 31. Namely, decreasing of the light amount is caused for the fact that, at wavelengths of the first inspection light 6 and the second inspection light 9, the reflection index of the metal layer 30 is greater than the reflection index of the barrier film 31.

After starting of decreasing of the light amount, the light amount is decreased so that the first averaged data “c” and the second averaged data “d” have substantially the same light amount decreasing ratio up to a certain timing. From the certain timing, either the first averaged data “c” or the second averaged data “d”, for example, the first averaged data “c”, may have greater light amount decreasing than that in the second averaged data “d”. The reason why difference in decreasing of the light amount is caused is that after removal of the barrier layer 31, the reflection indexes of the lower layer structure are different between the first inspection light 6 and the second inspection light. For example, in the following disclosure, the reflection index of the first inspection light is greater than the reflection index of the second inspection light 9.

According to progress of polishing, the barrier film 31 becomes thinner to start to pass through the light. Then, the reflection index of the lower layer starts to influence for the light amount. Due to difference of reflection indexes at difference wavelength in the lower layer, the first averaged data “c” and the second averaged data “d” become different to crease a difference therebetween. On the other hand, after the polishing end point, the difference between the first averaged data “c” and the second averaged data “d” becomes substantially constant. The reason is that according to progress of polishing, the surface exposed is varied from the metal layer 30 to the barrier film 31, and then from the barrier film 31 to the lower structure, i.e. the insulation layer 29. Once the lower structure, i.e. the insulation layer 29, is exposed, the surface is not varied any further.

Strictly, due to variation of layer thickness in the lower structure, interference condition of the light may be varied to slightly vary the first averaged data “c” and the second averaged data “d”. However, in comparison with variation set forth above, the variation speed is significantly low. Therefore, with the length of period to make judgment whether the difference becomes constant, it can be discriminated from the variation of the light amount before the polishing endpoint.

Accordingly, the polishing endpoint can be detected by monitoring variation of difference of the decreasing ratio of the first averaged data “c” and the second averaged data “d” and detecting a timing where the difference between the first averaged data “c” and the second averaged data “d” becomes constant. Therefore, by deriving the difference between the first averaged data “c” and the second averaged data “d”, the polishing endpoint is detected by detecting a timing where the difference between the first averaged data and the second averaged data becomes substantially constant.

It should be noted that the reflection index after removal of the barrier film 31, is determined by interference in the insulation layer 29 as undercoat layer after removal of the barrier film 31. Therefore, the wavelength of the first inspection light and the wavelength of the second inspection light are selected so that the reflection index at the metal layer 30 is higher than the reflection index at the barrier film 31. Furthermore, in consideration of the reflection index due to interference at the insulation layer 29 after removal of the barrier film 31, the wavelength of the first inspection light 6 and the wavelength of the second inspection light 9 are selected to have large difference between a ratio of reflection index at the metal layer 30 and the reflection index due to interference at the insulation layer 29 in the wavelength of the first inspection light 6, and a ratio of reflection index at the metal layer 30 and the reflection index due to interference at the insulation layer 29 in the wavelength of the second inspection light 9.

Upon calculation of the difference between the first averaged data “c” and the second averaged data “d”, difference of the measuring condition of the first averaged data “c” and the second averaged data “d” is corrected to make the reference of variation amount consistent. As this reference, a measured value when the entire surface is covered with the metal layer 30, is used.

At first, the first reference light amount detecting means 23 and the second reference light amount detecting means 33 detect maximum values or averaged values of the first averaged data “c” and the second averaged data “d” during a period from the end of the disabled condition of the polishing endpoint detection at the initial stage of polishing by the initial variation canceling means 21 to judgment of starting of detection of the polishing endpoint by the detection start judgment means 22, for outputting as a first reference light amount value “e” and a second reference light amount value “f”. The light amount correcting means 24 derives a ratio of the first reference light amount value “e” and the second reference light amount value “f” output from the first reference light amount detecting means 23 and the second reference light amount detecting means 33 and multiplies the second averaged data “d” by the derived ratio of the first reference light amount value “e” and the second reference light amount value “f” to output as a corrected light amount data “g”.

Next, the light amount difference calculating means 25 calculates a difference between the first averaged data “c” and the corrected light amount data “g” to output a light amount difference data “h”. Using this light amount difference data “h”, the polishing endpoint is detected. As set forth above, at the polishing endpoint, the light amount difference data “h” becomes substantially constant. For this purpose, a differentiated value of the light amount difference data “h” for detecting the timing where the differentiated value becomes close to zero.

It should be noted that since the light amount difference data “h” has fine error component, the difference values may be derived at a plurality of measuring point to use the averaged value thereof for judgment of the polishing endpoint. Namely, by first averaged gradient deriving means 27, among the light amount difference data “h” output from the light amount difference calculating means 25, a value derived by averaging a plurality of retraced data and the currently measured data, the value derived by averaging a plurality of retraced data of the light amount difference data at a past timing are connected to derives an averaged gradient for outputting as a first gradient data “j”. A first polishing endpoint detecting means 28 compares the first averaged gradient data with a first endpoint judgment threshold value “i”. If the first averaged gradient data “j” becomes greater than or equal to the first endpoint judgment threshold value “i”, continuously for a number of times greater than or equal to a given times, if the value of the first averaged gradient data becomes greater than or equal to the first endpoint judgment threshold value “i” for a times greater than or equal to the predetermined times in total from a timing where the absolute value of the averaged gradient becomes greater than or equal to the predetermined value, or if a ratio of the first averaged gradient data “j” greater than or equal to the first endpoint judgment threshold value becomes greater than or equal a predetermined ratio, judgment is made that polishing of wafer 1 is finished.

The first endpoint judgment threshold value “i” for detecting the polishing endpoint is derived by multiplying the first reference light amount value “e” by the predetermined value by the first threshold value calculating means 26. This is for accommodate fluctuation of the light amount in the light source to make the judgment reference constant by making the first endpoint judgment threshold value i as a function of the first reference light amount value “e”.

A reason why the laser beam is employed as the inspection light is as follow. Upon polishing of the wafer 1, the polisher 4 is rotated to splash the polishing fluid 17 to the circumference by the centrifugal force. When the polishing fluid 17 deposits on the light emitting surface of the light source of light receiving surface of the photodetector, a part of the inspection light is blocked to cause degradation precision in detection. Therefore, the light source and the photodetector cannot be placed sufficiently close to the wafer 1. On the other hand, upon removing the polishing fluid 17 by blowing the air 16, if the polishing fluid 17 is completely removed so as not to reside on the surface of the wafer 1, abrasive particle contained in the polishing fluid 17 may stick on the surface of the wafer 1 to cause scratch or the like. Therefore removal of the polishing fluid 17 has to be done to leave the fluid layer in certain extent. Then, slight fluctuation should be caused in the reflection light from the wafer 1 due to presence of the fluid film on the wafer 1. Therefore, size of the light receiving surface of the photodetector has to be selected so that the reflected light from the wafer 1 may not misaligned out of the light receiving surface even when fluctuation due to the polishing fluid film is caused.

Accordingly, since the light source and the photodetector has to be placed away from the wafer 1 in certain extent and when the light source and the photodetector are placed distant from the wafer 1, all of the reflected light of diffusing light from the wafer 1 may not be received to cause fluctuation of light receiving amount due to fluctuation of the fluid film of the polishing fluid 17. Therefore, the laser light source which can reach the inspection light to long distance without causing diffusion of the light is most preferred, In the shown embodiment, while two inspection lights having difference wavelength are employed, the number of the inspection light is not limited to two.

The reflection index after removal of the barrier film 31, is determined by interference in the insulation layer 29 as undercoat layer after removal of the barrier film 31. Therefore, when a plurality of kinds of wafers 1 with different film thickness of insulation layer 29 are polished, it is possible that polishing endpoint cannot be detected when the reflection index resulting from interference in the insulation layer 29 accidentally matches with the reflection index in the barrier film 31 so as not to cause difference between the decreasing ratios of the first averaged data “c” and the second averaged data “d”. In this case, three or more inspection lights having respectively different wavelength are used. Among those three or more inspection lights, with three different combinations respectively consisted of two inspection lights (assuming three inspection lights are A to C, possible combinations are a combination of A and B, a combination of B and C and a combination of A and C), polishing endpoint detecting operations may be performed in parallel to accurately detect the polishing endpoint of the wafer 1.

By providing three or more inspection lights with different wavelengths, a plurality of kinds of wafers 1 with different film thickness are polished, any one of different combination of two inspection lights out of three or more inspection lights may cause difference of the decreasing ratio of the averaged data, and any of the combination, the polishing endpoint is detected.

In theory, even when three inspection lights with mutually different wavelengths are used, it is still possible to cause a condition where no difference is caused between the decreasing ratio of the averaged data. However, by employing three wavelength, a range of the film thickness where the any combinations of the wavelengths may have reflection index not causing difference in the decreasing ratio becomes quite narrow. Therefore, in practical use, three wavelengths should be sufficient. However, naturally, the inspection lights may provided four or more mutually different wavelengths to form mutually distinct combinations respectively having two out of four or more of wavelengths to perform polishing endpoint detecting operation in parallel.

Kinds of the layer thickness of the insulation layer 29 of the wafer 1 as object for polishing is not infinite in number, and in the actually manufactured wafers 1, only several kinds are used in discrete manner, and kind and range of insulation layer thickness are known to be detected the polishing endpoint by two mutually different wavelengths, two inspection lights may be advantageously employed as in the foregoing embodiment for compact size of the device and lower cost.

It should be noted that, for separately measuring the reflected light per each wavelength employing two or more laser beams of a plurality of mutually different wavelengths, in addition to provide mutually different light axes as in the shown embodiment, it is also possible to irradiate the laser beam in coaxial fashion to separate on light reception side employing a light splitting means, such as a wavelength selection filter, wavelength selection mirror, diffraction grating or the like. In this case, a multi-line laser oscillating multi-wavelengths may be used.

The foregoing first averaging means 19 to the first polishing endpoint detecting means 28 may be realized by software of the computer. Also, it can be realized as a hardware circuit employing an analog circuit or relay circuit or the like, or as a combination of the hardware circuit and the software.

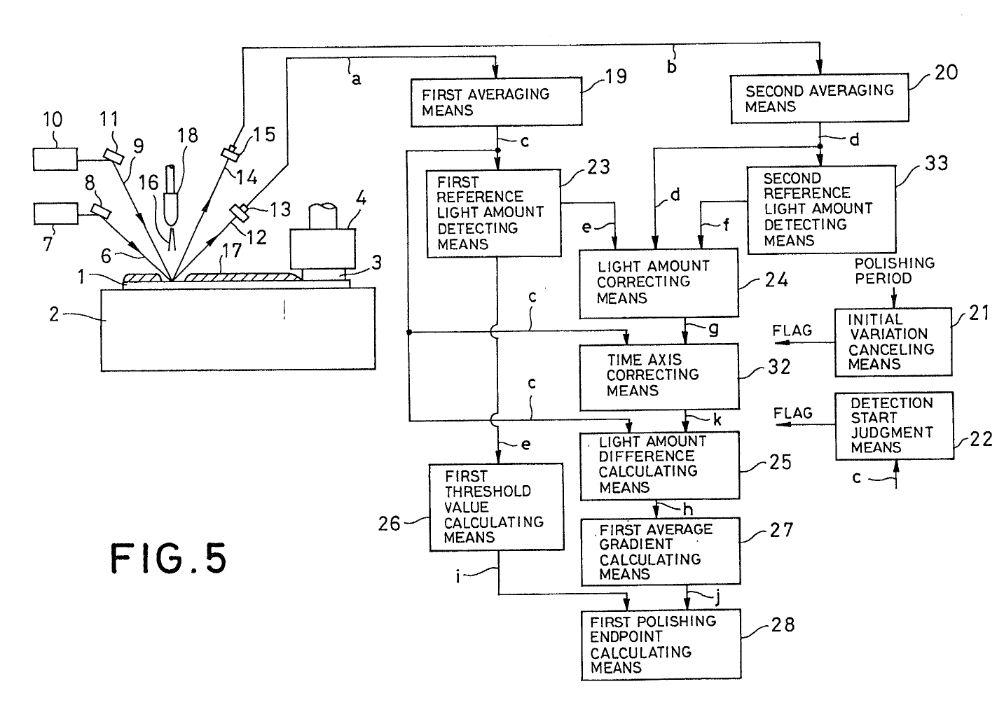

FIG. 5 is a block diagram showing a construction of the second embodiment of the wafer polishing endpoint detecting system according to the present invention. In the following disclosure, like reference numerals identify like components to those in the former embodiment and detailed discussion for such common components will be omitted in order to avoid redundant disclosure and whereby for keeping the disclosure simple enough to facilitate clear understanding of the present invention. The second embodiment of the wafer polishing endpoint detection system is added a time axis correction means 32 between the light amount correcting means 24 and the light amount difference calculating means 25. The time axis correction means 32 receives the corrected light amount data “g” output from the light amount correcting means 24, detects a timing where the difference between the first averaged value “c” and the corrected light amount signal becomes the minimum by comparing the value of the first averaged signal “c” at a timing decreased from the maximum value of the first averaged value “c” in a predetermined ratio or a predetermined amount and the value of the corrected light amount signal before or after the timing where the first averaged value “c” is decreased from the maximum value of the first averaged value “c” for deriving the difference of timing between two timings as time shift and outputting a second corrected light amount “k” by shifting the time axis of the corrected light amount data “g” in an amount corresponding to the derived time shift, in order to correct time shift of variation timing of the first averaged data “c” and the second averaged data “d”.

While the first embodiment derives a difference between the first average data “c” and the corrected light amount data “g” by the light amount difference calculating means 25, the shown second embodiment is featured by adding the time axis correcting means between the light amount correcting means 24 and the light amount difference calculating means 25 for correcting the time shift of the variation timing of the first averaged data “c” and the second averaged data “d” and deriving the difference the difference between the first averaged data “c” and the second corrected light amount data “k” corrected even in the time axis direction by the light amount difference calculating means 25. Accordingly, other than the time axis correcting means 32 are the same in constructions and operations. Therefore, discussion will be given only for operation of the time axis correcting means 32.

The shown second embodiment is applied for the case where the irradiating positions and irradiation diameters of the first inspection light 6 and the second inspection light 9 are different, and fluctuation is caused in polishing speed in radial direction of the wafer 1 to cause offset in variation of the first averaged data c and the second averaged data d in time direction.

Irradiating positions and the irradiation diameters of the first inspection light 6 and the second inspection light 9 do not become completely consistent. If error is contained in the irradiating position and the irradiation diameter, the first photodetector and the second photodetector should measure the reflection lights from mutually different regions. At this time, if the polishing speed fluctuates in the radial direction of the wafer 1, offset in time direction should be caused in variation of the first averaged data “c” and variation of the second averaged data “d”.

Therefore, in such case, if a difference between the first averaged data “c” and the corrected light amount data “g” is calculated by the light amount difference calculating means 25 as it is, correct light amount difference data depending upon variation of the surface of wafer 1 cannot be obtained. Therefore, error in time direction of variation of the first averaged data “c” and variation of the second averaged data “d” is corrected.

Particularly, a value of the first averaged data Each at a timing where the first averaged data “c” is decreased from the maximum value in the predetermined ratio or the predetermined amount and a value of the corrected light amount data “g” before and after the timing where the first averaged data “c” is decreased from the maximum value in the predetermined ratio or the predetermined amount are compared to detect a timing where the difference becomes minimum to calculate “a” time difference between two timings as an offset period to calculate a second corrected light amount data “k” shifted the time axis of the corrected light amount data “g” for the offset period. Subsequently, in place of the corrected light amount data, the second corrected light amount data “k” to perform polishing endpoint detection in the similar matter to the above.

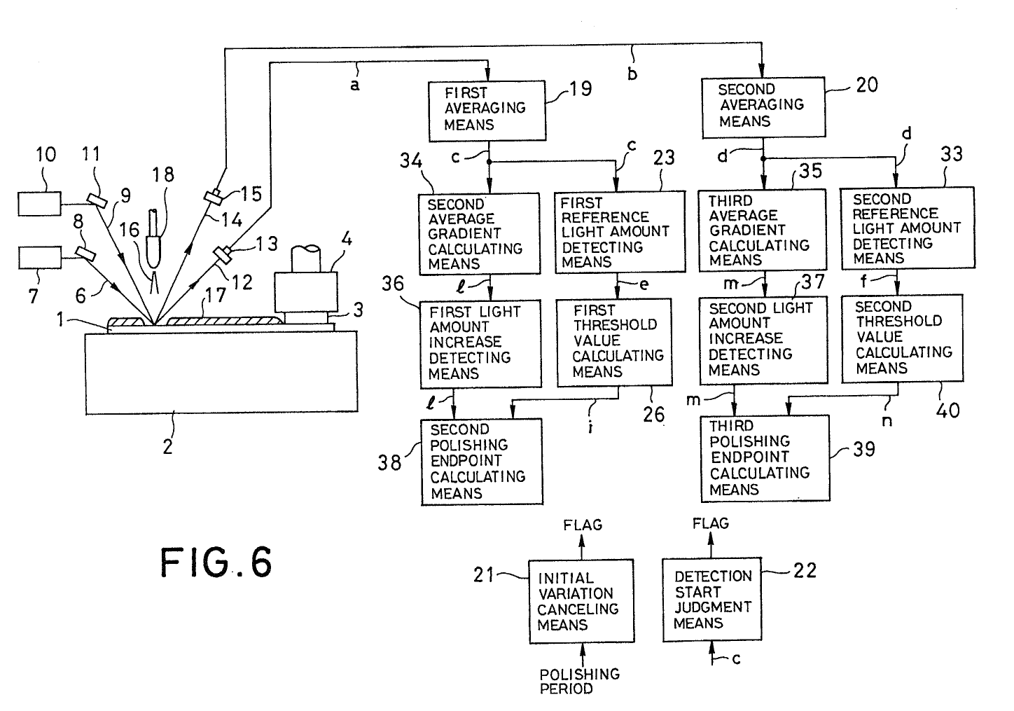

FIG. 6 is a block diagram showing a construction of the third embodiment of the wafer polishing endpoint detecting system according to the present invention. In the following disclosure, like reference numerals identify like components to those in the former embodiment and detailed discussion for such common components will be omitted in order to avoid redundant disclosure and whereby for keeping the disclosure simple enough to facilitate clear understanding of the present invention. The third embodiment of the wafer polishing endpoint detecting system of FIG. 6 employs second averaged gradient calculating means 34 and third averaged gradient calculating means 35 which calculates averaged gradients by connecting an averaged value of a plurality of retraced past data and the value at the current timing among the first averaged data “c” and the second averaged data “d” and an averaged data of a plurality of retraced past light amount difference data for outputting as a second averaged gradient data “l” and a third averaged gradient data “m”, first light amount increase detecting means 36 and second light amount increase detecting means 37 detecting the second averaged gradient data “l” and the third averaged gradient data “m” in positive value, second threshold value calculating means 40 for outputting a value derived by multiplying the second reference light amount data “f” output from the second reference light amount detecting means 33 by a predetermined value as a second endpoint judgment threshold value “n” for detecting the polishing endpoint on the side of the second inspection light 9, and second polishing endpoint detecting means 38 and the third polishing endpoint detecting means 39 for comparing the value of the second averaged gradient data “l” and the first endpoint judgment threshold value “i” and the value of the third averaged gradient data “m” and the second endpoint judgment threshold value “n” after the first light amount increase detecting means 36 and the second light amount increase detection means 37 detect the second averaged gradient data “l” and the third averaged gradient data “m” in positive for making judgment of end of polishing when the values of the second averaged gradient data “l” and the third averaged gradient data “m” become values greater than or equal to the endpoint judgment threshold values continuously for a predetermined number of times or more, when the second averaged gradient data “l” and the third averaged gradient data “m” become the value greater than or equal to the endpoint judgment threshold values for a number of times greater than or equal to the predetermined times in total, or when ratio of the second averaged gradient data “l” and the third averaged gradient data “m” becoming greater than or equal to the endpoint judgment threshold value in a ratio greater than or equal to a predetermined ratio, are provided in place of the light amount correcting means 24, the light amount difference calculating means 25, the first gradient calculating means 27 and the first polishing endpoint detecting means 28.

While the first embodiment detects the polishing end point on the basis of the fact that the difference of decreasing ratio of the first averaged data “c” and the second averaged data “d” are varied toward the polishing end point, and, after the polishing end point, the difference between the first averaged data “c” and the second averaged data “d” become substantially constant, whereas the shown third embodiment of the wafer polishing endpoint detecting system performs detection of the polishing endpoint on the basis of the fact that the first averaged value “c” or the second averaged value “d” is increased once before the polishing endpoint and subsequently becomes substantially constant or is decreased after the polishing endpoint.

Accordingly, after the second averaged gradient calculating means 33 and the third averaged gradient calculating means 34, operation is the same as the first embodiment except for detecting operation of the polishing endpoint. Therefore, the following discussion will be given only for operation after the second averaged gradient calculating means 33 and the third gradient calculating means 34.

In the wavelength of the first inspection light 6 or the second inspection light 9, it is possible in certain kind of the barrier film 31 and the certain lower layer structure to be exposed at the polishing endpoint that the reflection index of the barrier film 31 is smaller than the reflection index of the lower layer structure exposed at the polishing endpoint. In the graph shown in FIG. 3 in the discussion for the first embodiment of the wafer polishing endpoint detection system, the second averaged data “d” may correspond. In this case, the first averaged data “c” or the second averaged data “d” is once risen at a timing where the barrier film 31 is exposed and the reflection index of the lower layer structure influences after significantly lowering the signal, and after polishing endpoint, is maintained substantially constant or again lowered.

In such case, a differential value of the first averaged data “c” or the second averaged data “d” is calculated, to take a timing where the sign of the differential value once becomes “positive” and then the value becomes close to zero, as polishing endpoint. However, since the light amount signal contains fine error, similarly to the first embodiment, as the differential value, an averaged gradient including the past value may be used.

At first, the second averaged gradient calculating means 33 and the third averaged gradient calculating means 34 calculate averaged gradients by connecting an averaged value of a plurality of retraced past data and the value at the current timing among the first averaged data “c”, and the second averaged data “d” and an averaged data of a plurality of retraced past light amount difference data for outputting as a second averaged gradient data “l” and a third averaged gradient data “m”.

The first light amount increase detecting means 36 and second light amount increase detecting means 37 detect the second averaged gradient data “l” and the third averaged gradient data “m” in positive value.

On the other hand, as the threshold value for making judgment of the polishing end point on the side of the second inspection light, similarly to that on the side of the first inspection light 6, the second threshold value calculating means 40 outputs the value derived by multiplying the second reference light amount value “f” output from the second reference light amount detection means 33 and the predetermined value as the second endpoint judgment threshold value “n” for detecting the polishing endpoint.

The second polishing endpoint detecting means 38 and the third polishing endpoint detecting means 39 compares the value of the second averaged gradient data “l” and the first endpoint judgment threshold value “i” and the value of the third averaged gradient data “m” and the second endpoint judgment threshold value “n” for making judgment of end of polishing when the values of the second averaged gradient data “l” and the third averaged gradient data “m” become values smaller than or equal to the endpoint judgment threshold values continuously for a predetermined number of times or more, when the second averaged gradient data “l” and the third averaged gradient data “m” become the value smaller than or equal to the endpoint judgment threshold values for a number of times greater than or equal to the predetermined times in total after the absolute value of the averaged gradiant becomes greater than or equal to the predetermined value, or when a ratio that the second averaged gradient data “l” and the third averaged gradient data “m” become smaller than or equal to the endpoint judgment threshold value is greater than or equal to a predetermined ratio.

Among two of the first averaged data “c” obtained on the side of the first inspection light 6 and the second averaged data “d” obtained on the side of the second inspection light 9, which data shows variation applicable for the third embodiment depends on the wavelengths of the first inspection light 6 or the second inspection light 9, and the reflection index at the barrier layer 31 in the wavelength and the reflection index of the case where the lower layer structure is exposed at the timing of end of polishing. The reflection index of the lower structure is variable depending upon interference at the insulation layer 29. Therefore, in the third embodiment, polishing endpoint detection is performed in parallel on both of the first inspection light 6 side and the second inspection light 9 side for detecting the polishing endpoint by either one.

At this time, number of the inspection light is not specifically limited to two. The reflection index of the lower layer structure is varied by interference in the insulation layer 29. It is therefore possible that signal variation applicable for the third embodiment is not obtained by using either inspection light, depending on the thickness of the insulation layer 29, if the wavelengths of the inspection lights are only two. In such case, respectively different three or more inspection lights are used to detect the polishing endpoint in parallel with each other so that by any one of the inspection lights the polishing endpoint may be detected. On the other hand, if the layer thickness of the insulation layer 29 of the wafer 1 as object is limited, and the reflection index of the barrier film 31 at the polishing endpoint is smaller than the reflection index in the case where the lower layer structure is exposed, the inspection light may be one.

It is also possible to apply the third embodiment set forth above in combination with the first embodiment or the second embodiment.

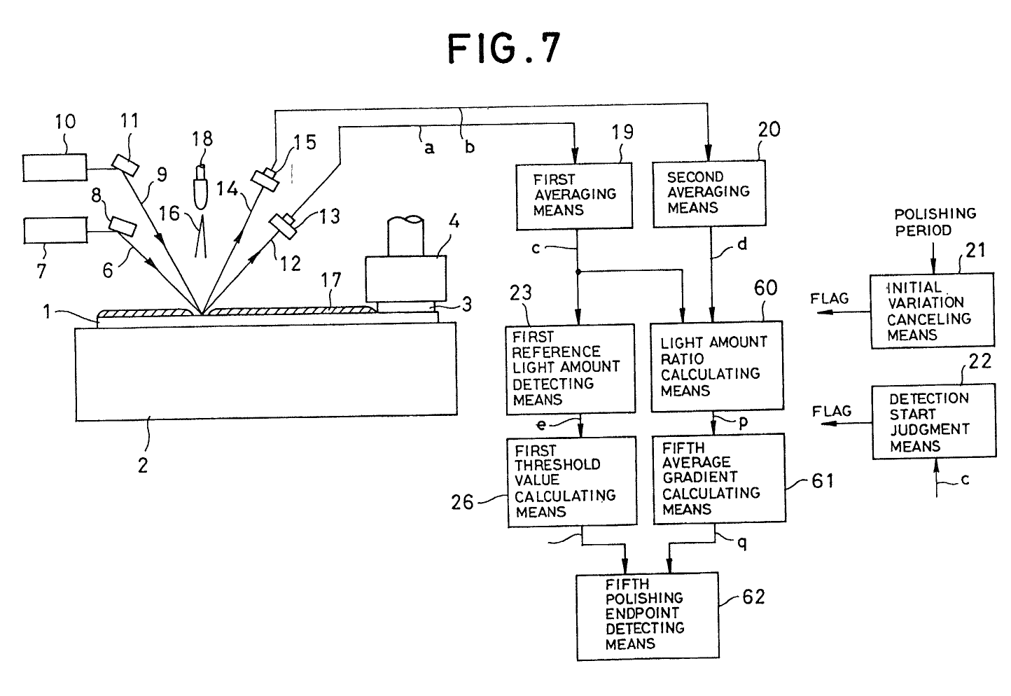

FIG. 7 is a block diagram showing a construction of the fourth embodiment of the wafer polishing endpoint detecting system according to the present invention. In the following disclosure, like reference numerals identify like components to those in the former embodiment and detailed discussion for such common components will be omitted in order to avoid redundant disclosure and whereby for keeping the disclosure simple enough to facilitate clear understanding of the present invention.

The fourth embodiment of the wafer polishing endpoint detecting system is constructed by omitting the second reference light amount detecting means 33 and the light amount correcting means 24 and providing light amount ratio calculating means 60 for receiving the first averaged data “c” and the second averaged data “d” for calculating a ratio of the first averaged data “c” and the second averaged data “d” to output a light amount ratio data “p”, fifth gradient calculating means 61 for receiving the light amount ratio data “p”, calculating an averaged gradient by connecting an averaged value of a plurality of retraced light amount ratio data in the past and the value at the current measuring timing, and an averaged value of a plurality of data of the past timing of the light amount ratio data p for outputting as a fifth averaged gradient data “q”, and fifth polishing endpoint detecting means 62 receiving the fifth averaged gradient data “q” and the first endpoint judgment threshold value “i” for comparing the value of the fifth averaged gradient data “q” and the value of the first endpoint judgment threshold value “i” for making judgment of end of polishing when the value of the fifth averaged gradient data “q” becomes a value greater than or equal to the first endpoint judgment threshold value “i” continuously for a predetermined number of times or more, when the value of the fifth averaged gradient data “q” becomes the value greater than or equal to the first endpoint judgment threshold value “i” for a number of times greater than or equal to the predetermined times in total after the absolute value of the averaged gradiant becomes greater than or equal to the predetermined value, or when a ratio that the value of the fifth averaged gradient data “q” becomes greater than or equal to the first endpoint judgment threshold value “i” is greater than or equal to a predetermined ratio, in place of the light amount difference calculating means 25, the first gradient calculating means 27 and the first polishing endpoint detecting means 28.

The first embodiment set forth above performs detection of the polishing endpoint using the light amount difference data “h” as a difference between the first averaged data “c” and the corrected light amount data “g” derived by correcting the second averaged data “d”, whereas the shown fourth embodiment is characterized in detection of the polishing end point using the light amount ratio data “p” as a ratio of the first averaged data “c” and the second averaged data d.

Accordingly, the detecting operation of the polishing endpoint except for the operation subsequent to the light amount ratio calculating means 60 is the same as those in the first embodiment. Therefore, in the following disclosure, only operation after the light amount ratio calculating means 60 will be discussed.

The fourth embodiment is particularly applicable for two step polishing process, in which polishing is interrupted once when the barrier film 31 is exposed and polishing is performed with replacing the polishing fluid, upon polishing the wafer of the structure illustrated in FIG. 2.

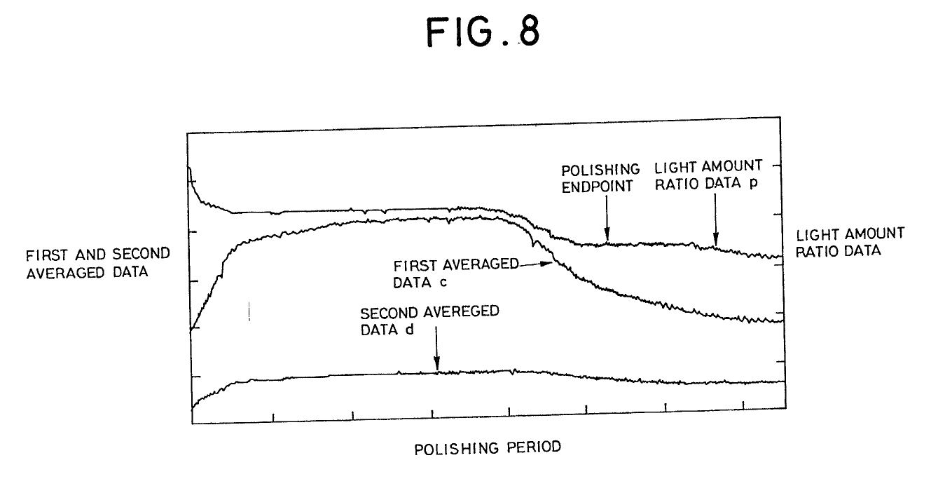

FIG. 8 is a graph showing one example of variation of the first averaged data “c”, the second averaged data “d” and the light amount ratio data “p” in the process where polishing is terminated when the barrier layer 31 is exposed, in polishing the wafer 1 with the barrier film 31 as shown in FIG. 2.

At this time, a ratio of the reflection index of the metal layer 30 and the reflection index of the barrier layer 31 is greater at the wavelength of the first inspection light 6 than the wavelength of the second inspection light 9. Namely, when the metal layer 30 is polished and the barrier layer 31 is exposed, variation of the light amount signal is greater in the first averaged data as the signal of the first inspection light 6 than the second averaged data “d” as the signal of the second inspection light 9.

As discussed with respect to the first embodiment, the first averaged data “c” and the second averaged data “d” become smaller at greater transmission of the light through the metal layer 30 having high reflection index, according to progress of polishing, or from a timing where a part of the metal layer 30 is removed and thus the barrier layer 31 having smaller reflection index starts to influence. By further progress of polishing, the light amount is decreased further. Even after end of polishing where the barrier layer 31 is completely exposed, the light amount is continued to be decreased. This is because dishing, erosion or the like on the formed wiring portion to make the surface of the wafer 1 not flat for reducing regular reflection component, the barrier layer 31 being polished continuously, and influence of the reflection index of the insulation layer 29 becomes stronger. Accordingly, the polishing endpoint cannot be detected by light amount variation in single wavelength.

Decreasing of regular reflection component due to dishing or erosion and influence of reflection index of the insulation layer 29 upon reducing thickness of the barrier film 31 by continuing polishing influence both for the first averaged data “c” and the second averaged data “d”, equally. Therefore, by calculating the ratio of the first averaged data “c” and the second averaged data “d”, influence of these can be canceled.

Accordingly, the light amount ratio data “p” as the ratio of the first averaged data “c” and the second averaged data “d” is determined variation only by the ratio of reflection index of the first inspection light 6 and the reflection index of the second inspection light 9 in the metal layer 30 and the barrier film 31.

At this time, the ratio of the reflection index at the metal layer 30 and the reflection index at the barrier film 31 is greater in the wavelength of the first inspection light 6 than in the wavelength of the second inspection light 9. Namely, when the metal layer 30 is polished and the barrier layer 31 is exposed, variation of the light amount signal on the first averaged data “c” as the signal of the first inspection light 6 is greater than the second averaged data “d” as the signal of the second inspection light. Therefore, the light amount ratio “p” becomes smaller when the barrier layer 31 starts to be exposed, and becomes constant when the barrier layer 31 is completely exposed.

In the fourth embodiment, a differential value of the light amount ratio data “p” is calculated to detect the polishing endpoint when the sign of the differential value becomes “negative” and then becomes a value close to zero. However, since the light amount data has fine error component, as the differential value, an averaged gradient including past value is used. At first, the light amount ratio calculating means 60 calculates the ratio of the first averaged data “c” and the second averaged data “d” to output as the light amount ratio data “p”. Next, the fifth averaged gradient calculating means 61 calculates an averaged gradient by connecting an averaged value of a plurality of retraced light amount ratio data in the past and the value at the current measuring timing, and an averaged value of a plurality of data of the past timing of the light amount ratio data “p” for outputting as a fifth averaged gradient data “q”.

Finally, the fifth polishing endpoint detecting means 62 compares the value of the fifth averaged gradient data “q” and the value of the first endpoint judgment threshold value “i” for making judgment of end of polishing when the value of the fifth averaged gradient data “q” becomes a value greater than or equal to the first endpoint judgment threshold value “i” continuously for a predetermined number of times or more, when the value of the fifth averaged gradient data “q” becomes the value greater than or equal to the first endpoint judgment threshold value “i” for a number of times greater than or equal to the predetermined times in total after the absolute value of the averaged gradiant becomes greater than or equal to the predetermined value, or when ratio that the value of the fifth averaged gradient data “q” becomes greater than or equal to the first endpoint judgment threshold value “i” is greater than or equal to a predetermined ratio.

Conversely, when the ratio of the reflection index at the metal layer 30 and the reflection index at the barrier film 31 is greater in the wavelength of the second inspection light 9 than in the wavelength of the first inspection light 6, namely, when the metal layer 30 is polished and the barrier layer 31 is exposed, variation of the light amount signal on the second averaged data “d” as the signal of the second inspection light 9 is greater than the first averaged data “c” as the signal of the first inspection light 6, the light amount ratio “p” becomes greater when the barrier layer 31 starts to be exposed, and becomes constant when the barrier layer 31 is completely exposed.

In this case, the fifth polishing endpoint detecting means 62 compares the value of the fifth averaged gradient data “q” and the value of the first endpoint judgment threshold value “i” for making judgment of end of polishing when the value of the fifth averaged gradient data “q” becomes a value smaller than or equal to the first endpoint judgment threshold value “i” continuously for a predetermined number of times or more, when the value of the fifth averaged gradient data “q” becomes the value smaller than or equal to the first endpoint judgment threshold value “i” for a number of times greater than or equal to the predetermined times in total after the absolute value of the avereged gradiant becomes greater than or equal to the predetermines value, or when ratio that the value of the fifth averaged gradient data “q” becomes smaller than or equal to the first endpoint judgment threshold value “i” is greater than or equal to a predetermined ratio.

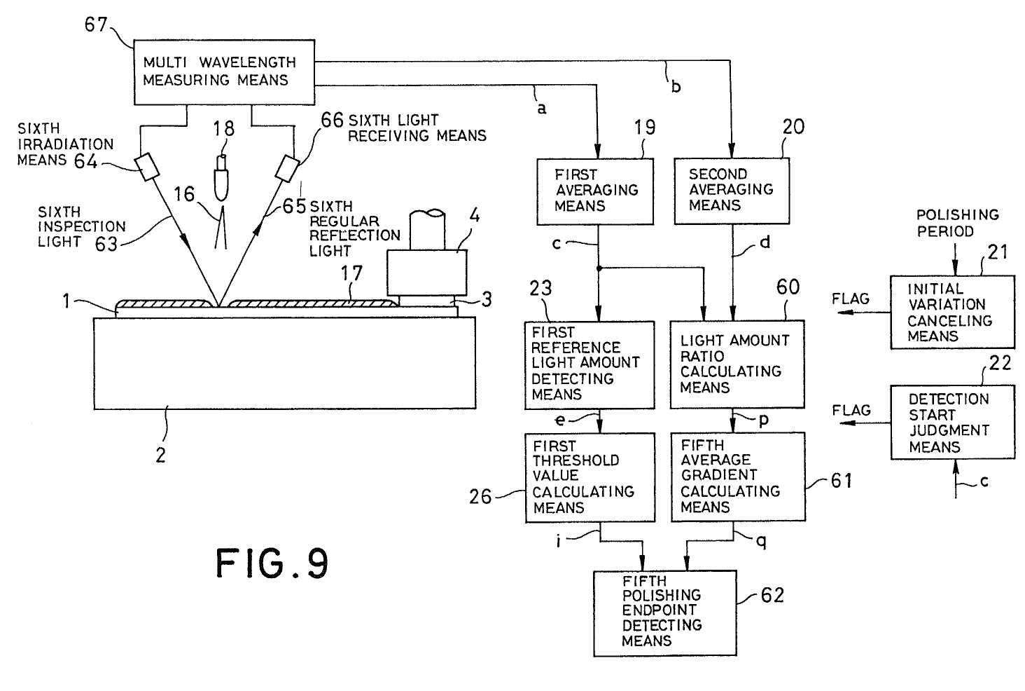

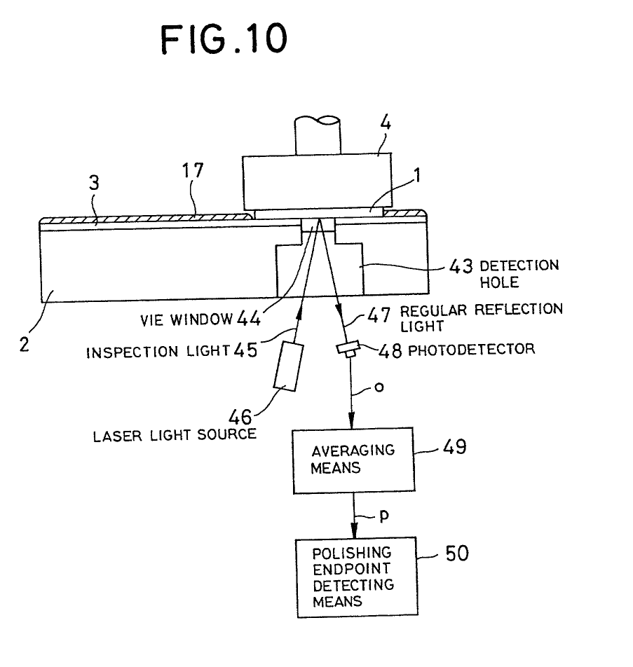

FIG. 9 is a block diagram showing a construction of the fifth embodiment of the wafer polishing endpoint detecting system according to the present invention. In the following disclosure, like reference numerals identify like components to those in the former embodiment and detailed discussion for such common components will be omitted in order to avoid redundant disclosure and whereby for keeping the disclosure simple enough to facilitate clear understanding of the present invention. The fifth embodiment of the wafer polishing endpoint detecting system of FIG. 9 is provided with a multi-wavelength measurement means 67 having a plurality of light sources respectively having different wavelength and one or more light receiving portion, irradiating a plurality of lights having different wavelengths on the same light axis as a sixth inspection light 63, receives a sixth regular reflection light as reflection light from the wafer 1 to measure light receiving amount per wavelengths for outputting a plurality of received light amount signals, sixth irradiating means 64 for guiding the sixth inspection light 63 including a plurality of wavelengths emitted from the multi-wavelength measuring means for irradiating to the wafer 1 at a predetermined diameter and a predetermined angle, and sixth light receiving means 66 for guiding the sixth regular reflection light 65 reflected from the wafer 1 to the multi-wavelength measuring means 67, in place of the first laser light source 7, the first irradiation means 8, the second laser light source 10, the second irradiating means 11, the first photodetector 13 and the second photodetector 15.

In the fourth embodiment, the light sources, irradiating means and the photodetector are provided per wavelength of the inspection light. In contrast to this, the shown fifth embodiment employs the multi-wavelength measuring means 67 for irradiating the sixth inspection light 63 including a plurality of wavelengths emitted from the multi-wavelength measuring means 67 through single sixth irradiating means 64 onto the surface of the wafer 1 at the predetermined diameter and the predetermined angle, and receiving the sixth regular reflection light 65 by the multi-wavelength measuring means 67 through one sixth light receiving means 66, for performing endpoint detection on the basis of manner of variation of the received light amount signal per wavelength emitted from the multi-wavelength measuring means 67, according to progress of polishing.

Accordingly, other than the multi-wavelength measuring means 67, the sixth irradiating means 64 and the sixth light receiving means 66 are equal in construction and operation to the fourth embodiment. Therefore, the following discussion will be concentrated to the operation of the multi-wavelength measuring means 67, the sixth irradiating means 64 and the sixth light receiving portion 66.

The multi-wavelength measuring means 67 has plurality of light sources having a plurality of light sources respectively having different wavelength and one or more light receiving portion, irradiating a plurality of lights having different wavelengths on the same light axis as a sixth inspection light 63, and receiving the sixth regular reflection light 65 as reflection light from the wafer 1 to measure the light receiving amount per wavelength for outputting a plurality of received light amount signals. As such multi-wavelength measuring means 67, a color sensor E3MC-Y81 available from Omron K.K. When color sensor E3MC-Y81 from Omron K.K. is to be used, as the sixth irradiating means 64, Fiber Unit E-32-T17L from Omron K. K. may be used, and as the sixth light receiving portion, Fiber Unit E32-T17L from Omron K. K. may be used.

The Color sensor E3MC-Y81 from Omron K. K. has three light sources, i.e., a red LED having a center wavelength of 680 nm, green LED having center wavelength of 525 nm, and blue LED having center wavelength of 450 nm and one light receiving portion to irradiate respective light in time division and light receiving amounts of respective lights are measured in time division to output as three received light amount signals.

When this color sensor E3MC-Y81 is taken as the multi-wavelength measuring means 67 in the fifth embodiment, among three received light amount signals of red, green and blue, two signals are selected as first light amount signal “a” and the second light amount signal “b”. Subsequently, detection of the polishing endpoint is performed in the same operation as the fourth embodiment.

Which two signals out of three received light amount signals are to be used is determined depending upon difference of the reflection index of respective wavelengths at the metal layer 30 and the barrier film 31. Combination of two signals with which variation of the light amount ratio data “p” is the largest is used. For example, when the material of the metal layer 30 is Cu and the material of the barrier film 31 is TaN or Ta, the first light amount signal “a” is the received light amount signal of red and the second light amount signal “b” is the received light amount signal of blue or green.

This is because the red has large ratio of reflection index with Cu and TaN or Ta, and blue or green has relatively small ratio of reflection index with Cu and TaN or Ta. Blue and green have substantially the same ratio of reflection index with Cu and TaN or Ta, either color of received light amount signal may be used.

It should be noted that the multi-wavelength measuring means 67, the sixth irradiation means 64 and the sixth light receiving means 66 may be integrated. As such integrated unit, color sensor E3MC-A81 from Omron K. K. may be used, for example.

As the sixth irradiating means 64 and the sixth light receiving means 66, an integrated unit, in which light emitting means and light receiving means are integrated, such as reflection type fiber unit E32-CC200 from Omron K. K. may be used, for example. Also, when sufficient light amount and stable regular reflection light sufficient for detection of the polishing endpoint can be obtained even when the polishing fluid 17 is present, air nozzle 18 may be omitted.

For instance while the foregoing first to fifth embodiments are discussed in terms of polishing of semiconductor wafer, the present invention is equally applicable for CMP (chemical mechanical polishing) performing polishing using the polishing fluid causing chemical reaction.

As set forth above, according to the present invention, since polishing endpoint is detected with a plurality of signals on the basis of variation of light amount of the reflected light of a plurality of mutually different wavelength associating with progress of polishing, even with the semiconductor wafer having the barrier film, the polishing endpoint can be detected accurately. Also, decreasing of the regular reflection component due to dishing or erosion in the wiring portion formed on the wafer and influence of the insulation layer upon polishing of barrier film can be canceled and more accurate polishing endpoint detection can be performed.

What is claimed is:

1. A semiconductor wafer polishing endpoint detecting system comprising:
a first laser light source as a light source for a first inspection light of a predetermined wavelength;
a first irradiation means for irradiating said first inspection light on said wafer with a predetermined diameter and a predetermined angle;
a second laser light source as a light source for a second inspection light of a wavelength different from that of said first inspection light;
a second irradiation means for irradiating said second inspection light to the same irradiating position and the same diameter as said first inspection light at a predetermined angle;
a first photodetector located on a regular reflection light axis of said first inspection light reflected on said wafer, receiving said regular reflection light for outputting a first light amount signal;
a second photodetector located on a regular reflection light axis of said second inspection light reflected on said wafer, receiving said regular reflection light for outputting a second light amount signal;
first averaging means and second averaging means for receiving said first light amount signal and said second light amount signal and averaging said first light amount signal and said second light amount signal per a period synchronous with an integer multiple of rotation period of said wafer in discrete manner for outputting a first averaged data and a second averaged data;
initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
detecting start judgment means for disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
first reference light amount detecting means and second reference light amount detecting means for detecting one of maximum values and averaged values of said first averaged data and said second averaged data during a period from polishing endpoint detection disabled condition by said initial variation canceling means to enabling of polishing endpoint detecting operation by said detection start judgment means to output as first reference light amount value and second reference light amount value;
light amount correcting means for calculating a ratio of said first reference light amount value and said second reference light amount value and multiplying said second averaged data by said ratio of said first reference light amount value and said second reference light amount value for outputting a corrected light amount data;
light amount difference calculating means for calculating a difference between said first averaged data and said corrected light amount data for outputting as a light amount difference data;
first threshold value calculating means for outputting a value derived by multiplying said first reference light amount value by a predetermined value as a first endpoint judgment threshold value for detecting polishing endpoint;
first averaged gradient calculating means for calculating an averaged gradient between an averaged value of a plurality of retraced past data and a data at current measuring timing of said light amount difference data and an averaged value of a plurality of past data of said light amount difference data; and
first polishing endpoint detecting means for comparing the value of said first averaged gradient data and said first endpoint judgment threshold value for making judgment of end of polishing of wafer when the value of said first averaged gradient data is greater than or equal to said first endpoint judgment threshold value continuously for a predetermined number of times, when the value of said first averaged gradient data is greater than or equal to said first endpoint judgment threshold value for a number of times greater than or equal to a given number of times in total after the absolute value of said first averaged gradient data becomes greater than or equal to a given value, or when a ratio that the value of said first averaged gradient data becomes greater than or equal to said first endpoint judgment threshold value is greater than or equal to a predetermined ratio.

2. A semiconductor wafer polishing end point detecting system as set forth in claim 1, which further comprises time axis correction means located between said light amount correcting means and said light amount difference calculating means for receiving said corrected light amount data output from said light amount correction means, detecting a timing where a difference between a value of said first averaged data at a timing where said first averaged data is decreased from a maximum value in a predetermined amount and a value of said corrected light amount signal before and after said timing where said first averaged data is decreased from a maximum value in a predetermined amount, becomes minimum, for deriving a time difference between two timings as offset period, and shifting a time axis of said corrected light amount for the derived offset period for outputting a second corrected light amount data to said light amount difference calculating means.

3. A semiconductor wafer polishing endpoint detecting system comprising:
a first laser light source as a light source for a first inspection light of a predetermined wavelength;
a first irradiation means for irradiating said first inspection light on said wafer with a predetermined diameter and a predetermined angle;
a second laser light source as a light source for a second inspection light of a wavelength different from that of said first inspection light;
a second irradiation means for irradiating said second inspection light to the same irradiating position and the same diameter as said first inspection light at a predetermined angle;
a first photodetector located on a regular reflection light axis of said first inspection light reflected on said wafer, receiving said regular reflection light for outputting a first light amount signal;
a second photodetector located on a regular reflection light axis of said second inspection light reflected on said wafer, receiving said regular reflection light for outputting a second light amount signal;
first averaging means and second averaging means for receiving said first light amount signal and said second light amount signal and averaging said first light amount signal and said second light amount signal per a period synchronous with an integer multiple of rotation period of said wafer in discrete manner for outputting a first averaged data and a second averaged data;
initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
detecting start judgment means for disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
first reference light amount detecting means and second reference light amount detecting means for detecting one of maximum values and averaged values of said first averaged data and said second averaged data during a period from polishing endpoint detection disabled condition by said initial variation canceling means to enabling of polishing endpoint detecting operation by said detection start judgment means to output as first reference light amount value and second reference light amount value;
light amount ratio calculating means for calculating a ratio of said first averaged data and said second averaged data for outputting a light amount ratio data;
first averaged gradient calculating means for calculating an averaged gradient between an averaged value of a plurality of retraced past data and a data at current measuring timing of said light amount ratio data and an averaged value of a plurality of past data of said light amount difference data;
first threshold value calculating means for outputting a value derived by multiplying said first reference light amount value by a predetermined value as a first endpoint judgment threshold value for detecting polishing endpoint; and
first polishing endpoint detecting means for comparing the value of said first averaged gradient data and said first endpoint judgment threshold value for making judgment of end of polishing of wafer when the value of said first averaged gradient data is greater than or equal to said first endpoint judgment threshold value continuously for a predetermined number of times, when the value of said first averaged gradient data is greater than or equal to said first endpoint judgment threshold value for a number of times greater than or equal to a given number of times in total after the absolute value of said first averaged gradient data becomes greater than or equal to a given value, or when a ratio that the value of said first averaged gradient data becomes greater than or equal to said first endpoint judgment threshold value is greater than or equal to a predetermined ratio.

4. A semiconductor wafer polishing endpoint detection system as set forth in claim 1, which uses at least three inspection lights as said inspection lights, mutually different combinations each consisted of two inspection lights are used in parallel for detecting the polishing endpoint.

5. A semiconductor wafer polishing endpoint detection system as set forth in claim 1, wherein said first polishing endpoint detecting means compares the value of said first averaged gradient data and a value of said first endpoint judgment threshold value for making judgment of end of polishing when the value of said first averaged gradient data is smaller than or equal to said first endpoint judgment threshold value continuously for a predetermined number of times, when the value of said first averaged gradient data is smaller than or equal to said first endpoint judgment threshold value for a number of times greater than or equal to a given number of times in total after the absolute value of said first averaged gradient data becomes greater than or equal to a given value, or when a ratio that the value of said first averaged gradient data becomes smaller than or equal to said first endpoint judgment threshold value is greater than or equal to a predetermined ratio.

6. A semiconductor wafer polishing endpoint detecting system comprising:
a first laser light source as a light source for a first inspection light of a predetermined wavelength;
a first irradiation means for irradiating said first inspection light on said wafer with a predetermined diameter and a predetermined angle;
a second laser light source as a light source for a second inspection light of a wavelength different from that of said first inspection light;
a second irradiation means for irradiating said second inspection light to the same irradiating position and the same diameter as said first inspection light at a predetermined angle;
a first photodetector located on a regular reflection light axis of said first inspection light reflected on said wafer, receiving said regular reflection light for outputting a first light amount signal;
a second photodetector located on a regular reflection light axis of said second inspection light reflected on said wafer, receiving said regular reflection light for outputting a second light amount signal;
first averaging means and second averaging means for receiving said first light amount signal and said second light amount signal and averaging said first light amount signal and said second light amount signal per a period synchronous with an integer multiple of rotation period of said wafer in discrete manner for outputting a first averaged data and a second averaged data;
initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
detecting start judgment means for disabling polishing endpoint detecting operation until one of said first averaged data or said second averaged data is varied to a predetermined value or a predetermined multiple for adapting to fluctuation in signal fluctuation period in the initial stage of polishing due to fluctuation of polishing speed;
first reference light amount detecting means and second reference light amount detecting means for detecting one of maximum values and averaged values of said first averaged data and said second averaged data during a period from polishing endpoint detection disabled condition by said initial variation canceling means to enabling of polishing endpoint detecting operation by said detection start judgment means to output as first reference light amount value and second reference light amount value;
first threshold value calculating means for outputting a value derived by multiplying said first reference light amount value by a predetermined value as a first endpoint judgment threshold value for detecting polishing endpoint second averaged gradient calculating means and third averaged gradient calculating means for calculating averaged gradients by connecting an averaged value of a plurality of retraced past data and the value at the current timing among the first averaged data and the second averaged data and an averaged data of a plurality of retraced past light amount difference data for outputting as a second averaged gradient data and a third averaged gradient data,
first light amount increase detecting means and second light amount increase detecting means detecting the second averaged gradient data and the third averaged gradient data in positive value,
second threshold value calculating means for outputting a value derived by multiplying the second reference light amount data output from the second reference light amount detecting means by a predetermined value as a second endpoint judgment threshold value for detecting the polishing endpoint on the side of the second inspection light, and
second polishing endpoint detecting means and the third polishing endpoint detecting means for comparing the values of the second and third averaged gradient data and the endpoint judgment threshold value after the first light amount increase detecting means and the second light amount increase detection means detect the second averaged gradient data and the third averaged gradient data in positive for making judgment of end of polishing when the values of the second averaged gradient data and the third averaged gradient data become values greater than or equal to the endpoint judgment threshold values continuously for a predetermined number of times or more, when the second averaged gradient data and the third averaged gradient data become the value greater than or equal to the endpoint judgment threshold values for a number of times greater than or equal to the predetermined times in total after the absolute value of said averaged gradient data becomes greater than or equal to a given value, or when a ratio that the second averaged gradient data and the third averaged gradient data become greater than or equal to the endpoint judgment threshold value becomes greater than or equal to a predetermined ratio.

7. A semiconductor wafer polishing end point detecting system as set forth in claim 6, wherein said second polishing endpoint detecting means and said third polishing endpoint detecting means compare the values of said second averaged gradient data and said third averaged gradient data and said endpoint judgment threshold value after detection of said second averaged gradient data and said third averaged gradient data become positive values, for making judgment of end of polishing when the values of the second averaged gradient data and the third averaged gradient data become values smaller than or equal to the endpoint judgment threshold values continuously for a predetermined number of times or more, when the second averaged gradient data and the third averaged gradient data become the values smaller than or equal to the endpoint judgment threshold values for a number of times greater than or equal to the predetermined times in total after the absolute value of the averaged gradient becomes greater than or equal to the predetermined value, or when a ratio that the second averaged gradient data and the third averaged gradient data become smaller than or equal to the endpoint judgment threshold value becomes greater than or equal to a predetermined ratio.

8. A semiconductor wafer polishing endpoint detecting system as set forth in claim 6, wherein at least three inspection lights having mutually different wavelength are used for detecting polishing endpoint in parallel.

9. A semiconductor wafer polishing endpoint detecting system as set forth in claim 6, wherein said inspection light is single to perform polishing end point alone.

10. A semiconductor wafer polishing endpoint detecting system a comprising:
multi-wavelength measurement means having a plurality of light sources respectively having different wavelength and one or more light receiving portion, irradiating a plurality of lights having different wavelengths on the same light axis as a sixth inspection light, receives a sixth regular reflection light as reflection light from the wafer to measure light receiving amount per wavelengths for outputting a plurality of received light amount signals;
sixth irradiating means for guiding the sixth inspection light including a plurality of wavelengths emitted from the multi-wavelength measuring means for irradiating to the wafer at a predetermined diameter and a predetermined angle;
sixth light receiving means for guiding the sixth regular reflection light reflected from the wafer to the multi-wavelength measuring means;
first averaging means and second averaging means for receiving said first light amount signal and said second light amount signal and averaging said first light amount signal and said second light amount signal per a period synchronous with an integer multiple of rotation period of said wafer in discrete manner for outputting a first averaged data and a second averaged data;
initial variation canceling means for disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
detecting start judgment means for disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
first reference light amount detecting means and second reference light amount detecting means for detecting one of maximum values and averaged values of said first averaged data and said second averaged data during a period from polishing endpoint detection disabled condition by said initial variation canceling means to enabling of polishing endpoint detecting operation by said detection start judgment means to output as first reference light amount value and second reference light amount value;
light amount correcting means for calculating a ratio of said first reference light amount value and said second reference light amount value and multiplying said second averaged data by said ratio of said first reference light amount value and said second reference light amount value for outputting a corrected light amount data;
light amount difference calculating means for calculating a difference between said first averaged data and said corrected light amount data for outputting as a light amount difference data;
first threshold value calculating means for outputting a value derived by multiplying said first reference light amount value by a predetermined value as a first endpoint judgment threshold value for detecting polishing endpoint;
first averaged gradient calculating means for calculating an averaged gradient between an averaged value of a plurality of retraced past data and a data at current measuring timing of said light amount difference data and an averaged value of a plurality of past data of said light amount difference data; and
first polishing endpoint detecting means for comparing the value of said first averaged gradient data and said first endpoint judgment threshold value for making judgment of end of polishing of wafer when the value of said first averaged gradient data is greater than or equal to said first endpoint judgment threshold value continuously for a predetermined number of times, when the value of said first averaged gradient data is greater than or equal to said first endpoint judgment threshold value for a number of times greater than or equal to a given number of times in total after the absolute value of said first averaged gradient data becomes greater than or equal to a given value, or when a ratio that the value of said first averaged gradient data becomes greater than or equal to said first endpoint judgment threshold value is greater than or equal to a predetermined ratio.

11. A semiconductor wafer polishing endpoint detecting system as set forth in claim 10, wherein said sixth irradiating means, said sixth light receiving means and said multi-wavelength measuring means are integrated in a single unit.

12. A semiconductor wafer polishing endpoint detecting system as set forth in claim 10, wherein said sixth irradiating means and said sixth light receiving means are integrated in a single unit.

13. A semiconductor wafer polishing endpoint detecting system as set forth in claim 1, which further comprises an air nozzle provided on upper surface side of said wafer and blowing at a predetermined pressure and a predetermined flow rate for removing a polishing fluid.

14. A semiconductor wafer polishing endpoint detecting method comprising the steps of:
emitting a first inspection light of a predetermined wavelength;
irradiating said first inspection light on said wafer with a predetermined diameter and a predetermined angle;
emitting a second inspection light of a wavelength different from that of said first inspection light;
irradiating said second inspection light to the same irradiating position and the same diameter as said first inspection light at a predetermined angle;
receiving said regular reflection light of said first inspection light for outputting a first light amount signal;
receiving said regular reflection light of said second inspection light for outputting a second light amount signal;
receiving said first light amount signal and said second light amount signal and averaging said first light amount signal and said second light amount signal per a period synchronous with an integer multiple of rotation period of said wafer in discrete manner for outputting a first averaged data and a second averaged data;
disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
detecting one of maximum values and averaged values of said first averaged data and said second averaged data during a period from polishing endpoint detection disabled condition by said initial variation canceling step to enabling of polishing endpoint detecting operation by said detection start judgment step to output as first reference light amount value and second reference light amount value;
calculating a ratio of said first reference light amount value and said second reference light amount value and multiplying said second averaged data by said ratio of said first reference light amount value and said second reference light amount value for outputting a corrected light amount data;
calculating a difference between said first averaged data and said corrected light amount data for outputting as a light amount difference data;
outputting a value derived by multiplying said first reference light amount value by a predetermined value as a first endpoint judgment threshold value for detecting polishing endpoint;
calculating an averaged gradient between an averaged value of a plurality of retraced past data and a data at current measuring timing of said light amount difference data and an averaged value of a plurality of past data of said light amount difference data; and
comparing the value of said first averaged gradient data and said first endpoint judgment threshold value for making judgment of end of polishing of wafer when the value of said first averaged gradient data is greater than or equal to said first endpoint judgment threshold value continuously for a predetermined number of times, when the value of said first averaged gradient data is greater than or equal to said first endpoint judgment threshold value for a number of times greater than or equal to a given number of times in total after the absolute value of said first averaged gradient data becomes greater than or equal to a given value, or when a ratio that the value of said first averaged gradient data becomes greater than or equal to said first endpoint judgment threshold value is greater than or equal to a predetermined ratio.

15. A semiconductor wafer polishing endpoint detecting method as set forth in claim 14, which further comprises the step of receiving said corrected light amount data output from said light amount correction means, detecting a timing where a difference between a value of said first averaged data at a timing where said first averaged data is decreased from a maximum value in a predetermined amount and a value of said corrected light amount signal before and after said timing where said first averaged data is decreased from a maximum value in a predetermined amount, becomes minimum, for deriving a time difference between two timings as offset period, and shifting a time axis of said corrected light amount for the derived offset period for outputting a second corrected light amount data to the step of calculating the light amount difference data.

16. A semiconductor wafer polishing endpoint detecting method comprising:
emitting a first inspection light of a predetermined wavelength;
irradiating said first inspection light on said wafer with a predetermined diameter and a predetermined angle;
emitting a second inspection light of a wavelength different from that of said first inspection light;
irradiating said second inspection light to the same irradiating position and the same diameter as said first inspection light at a predetermined angle;
receiving said regular reflection light of said first inspection light for outputting a first light amount signal;
receiving said regular reflection light of said second inspection light for outputting a second light amount signal;
receiving said first light amount signal and said second light amount signal and averaging said first light amount signal and said second light amount signal per a period synchronous with an integer multiple of rotation period of said wafer in discrete manner for outputting a first averaged data and a second averaged data;
disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
detecting one of maximum values and averaged values of said first averaged data and said second averaged data during a period from polishing endpoint detection disabled condition by said initial variation canceling means to enabling of polishing endpoint detecting operation by said detection start judgment means to output as first reference light amount value and second reference light amount value;
calculating a ratio of said first averaged data and said second averaged data for outputting a light amount ratio data;
calculating an averaged gradient between an averaged value of a plurality of retraced past data and a data at current measuring timing of said light amount ratio data and an averaged value of a plurality of past data of said light amount difference data;
calculating a ratio of said first reference light amount value and said second reference light amount value and multiplying said second averaged data by said ratio of said first reference light amount value and said second reference light amount value for outputting a corrected light amount data;
outputting a value derived by multiplying said first reference light amount value by a predetermined value as a first endpoint judgment threshold value for detecting polishing endpoint; and
comparing the value of said first averaged gradient data and said first endpoint judgment threshold value for making judgment of end of polishing of wafer when the value of said first averaged gradient data is greater than or equal to said first endpoint judgment threshold value continuously for a predetermined number of times, when the value of said first averaged gradient data is greater than or equal to said first endpoint judgment threshold value for a number of times greater than or equal to a given number of times in total after the absolute value of said first averaged gradient data becomes greater than or equal to a given value, or when a ratio that the value of said first averaged gradient data becomes greater than or equal to said first endpoint judgment threshold value is greater than or equal to a predetermined ratio.

17. A semiconductor wafer polishing endpoint detection method as set forth in claim 14, which uses at least three inspection lights as said inspection lights, mutually different combinations each consisted of two inspection lights are used in parallel for detecting the polishing endpoint.

18. A semiconductor wafer polishing endpoint detection method as set forth in claim 14, wherein in said step of detecting polishing endpoint, the value of said first averaged gradient data is compared with a value of said first endpoint judgment threshold value for making judgment of end of polishing when the value of said first averaged gradient data is smaller than or equal to said first endpoint judgment threshold value continuously for a predetermined number of times, when the value of said first averaged gradient data is smaller than or equal to said first endpoint judgment threshold value for a number of times greater than or equal to a given number of times in total after the absolute value of said first averaged gradient data becomes greater than or equal to a given value, or when a ratio that the value of said first averaged gradient data becomes smaller than or equal to said first endpoint judgment threshold value is greater than or equal to a predetermined ratio.

19. A semiconductor wafer polishing endpoint detecting method comprising of the steps:
emitting a first inspection light of a predetermined wavelength;
irradiating said first inspection light on said wafer with a predetermined diameter and a predetermined angle;
emitting a second inspection light of a wavelength different from that of said first inspection light;
irradiating said second inspection light to the same irradiating position and the same diameter as said first inspection light at a predetermined angle;
receiving said regular reflection light of said first inspection light for outputting a first light amount signal;
receiving said regular reflection light of said second inspection light for outputting a second light amount signal;
receiving said first light amount signal and said second light amount signal and averaging said first light amount signal and said second light amount signal per a period synchronous with an integer multiple of rotation period of said wafer in discrete manner for outputting a first averaged data and a second averaged data;
disabling polishing endpoint detecting operation from initiation of polishing to elapse of a predetermined period for preventing detection of signal variation before stabilizing of polishing at an initial stage of polishing unstability of polishing immediately after initiation of polishing and difference of initial condition before polishing;
disabling polishing endpoint detecting operation until said first averaged data or said second averaged data is varied to a predetermined value or a predetermined multiple for adapting to fluctuation in signal fluctuation period in the initial stage of polishing due to fluctuation of polishing speed;
detecting one of maximum values and averaged values of said first averaged data and said second averaged data during a period from polishing endpoint detection disabled condition by said initial variation canceling step to enabling of polishing endpoint detecting operation by said detection start judgment step to output as first reference light amount value and second reference light amount value;
outputting a value derived by multiplying said first reference light amount value by a predetermined value as a first endpoint judgment threshold value for detecting polishing endpoint;
calculating averaged gradients by connecting an averaged value of a plurality of retraced past data and the value at the current timing among the first averaged data and the second averaged data and an averaged data of a plurality of retraced past light amount difference data for outputting as a second averaged gradient data and a third averaged gradient data,
detecting the second averaged gradient data and the third averaged gradient data in positive value,
outputting a value derived by multiplying said first reference light amount by a predetermined value as a first endpoint judgment threshold value for detecting the polishing endpoint, and
comparing the values of the second averaged gradient data and the third averaged gradient data and the endpoint judgment threshold value after the second averaged gradient data and the third averaged gradient data become positive values, for making judgment of end of polishing when the values of the second averaged gradient data and the third averaged gradient data become values greater than or equal to the endpoint judgment threshold value continuously for a predetermined number of times or more, when the second averaged gradient data and the third averaged gradient data become the value greater than or equal to the endpoint judgment threshold value for a number of times greater than or equal to the predetermined times in total the absolute value of said averaged gradient becomes greater than or equal to the predetermined value, or when a ratio that the second averaged gradient data and the third averaged gradient data become greater than or equal to the endpoint judgment threshold value is greater than or equal to a predetermined ratio.

20. A semiconductor wafer polishing end point detecting method as set forth in claim 19, wherein in said step of detecting polishing endpoint, the values of said second averaged gradient data and the said third averaged gradient data are compared with said endpoint judgment threshold value after said second averaged gradient data and said third averaged gradient data become positive values, for making judgment of end of polishing when the values of the second averaged gradient data and the third averaged gradient data become values smaller than or equal to the endpoint judgment threshold values continuously for a predetermined number of times or more, when the second averaged gradient data and the third averaged gradient data become the value smaller than or equal to the endpoint judgment threshold values¥ for a number of times greater than or equal to the predetermined times in total the absolute value of said averaged gradient becomes greater than or equal to the predetermined value, or when a ratio that the second averaged gradient data and the third averaged gradient data become smaller than or equal to the endpoint judgment threshold value is greater than or equal to a predetermined ratio.

21. A semiconductor wafer polishing endpoint detecting method as set forth in claim 19, wherein at least three inspection lights having mutually different wavelength are used for detecting polishing endpoint in parallel.

22. A semiconductor wafer polishing endpoint detecting method as set forth in claim 19, wherein said inspection light is single to perform polishing end point alone.

23. A semiconductor wafer polishing endpoint detecting method as set forth in claim 14, which further comprises blowing an air at a predetermined pressure and a predetermined flow rate for removing a polishing fluid.
